(19) United States
(12) Patent Application Publication
(10) Pub. No.: US 2026/0082829 A1
(43) Pub. Date: Mar. 19, 2026

(54) GUNN DIODES FOR CLOCK SYNCHRONIZATION CIRCUITS

(71) Applicants: Abhishek A. Sharma, Portland, OR (US); Wilfred Gomes, Portland, OR (US); Tahir Ghani, Portland, OR (US)

(72) Inventors: Abhishek A. Sharma, Portland, OR (US); Wilfred Gomes, Portland, OR (US); Tahir Ghani, Portland, OR (US)

(21) Appl. No.: 18/887,273

(22) Filed: Sep. 17, 2024

(51) Int. Cl. H10N 89/00; H01L 27/06

(52) U.S. Cl. CPC H10N 89/00; H10D 84/811

(57) ABSTRACT

Disclosed herein are clock synchronization circuits using Gunn diodes, and related integrated circuit (IC) structures, devices, and techniques. In one aspect, an IC structure includes a first transistor, a second transistor, a first Gunn diode coupled to the first transistor, a second Gunn diode coupled to the second transistor, and a third transistor coupled between the first Gunn diode and the second Gunn diode.

### BACKGROUND

A Gunn diode, also referred to as a transferred electron device (TED), is a two-terminal device that is characterized by a current-voltage (I-V) curve with a region of negative differential resistance, or more generally, negative impedance. In general, impedance is a measure of opposition to the flow of alternating current in a circuit. Impedance encompasses resistance (which resists the flow of current) and reactance (which arises due to effects of capacitance in inductance). A Gunn diode is based on the Gunn effect, which produces oscillations along the negative differential resistance region. As the electric field applied to the diode increases, the current though the diode initially increases and then decreases in a cyclical manner, leading to periodic fluctuations in current. The current fluctuations produce high-frequency oscillations, typically in the microwave frequencies, e.g., between 300 megahertz (MHz) and 300 gigahertz (GHz).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates a cross-section of an integrated circuit (IC) structure with a Gunn diode, according to some embodiments of the present disclosure.

FIG. 2 illustrates example I-V curves for Gunn diodes disclosed herein, according to some embodiments of the present disclosure.

FIGS. 3A-3H are electric circuit diagrams of example clock synchronization circuits with Gunn diodes, according to some embodiments of the present disclosure.

FIG. 4 provides a perspective view of an example IC structure implementing a nanoribbon transistor that may be included in a clock synchronization circuit with Gunn diodes, in accordance with some embodiments.

FIG. 5 provides a perspective view of an example IC structure implementing a FinFET that may be included in a clock synchronization circuit with Gunn diodes, in accordance with some embodiments.

FIGS. 6A-6B provide different views of an example IC structure implementing a clock synchronization circuit with Gunn diodes when transistors M1-M3 are formed along a single stack of nanoribbons, according to some embodiments of the present disclosure.

FIGS. 7A-7D provide different views of an example IC structure implementing a clock synchronization circuit with Gunn diodes when transistors M1-M3 are formed along different stacks of nanoribbons, according to some embodiments of the present disclosure.

FIGS. 8A-8H are schematic illustrations of microelectronic assemblies with clock synchronization circuits with Gunn diodes, according to some embodiments of the present disclosure.

FIG. 9 illustrates top views of a wafer and dies that may include one or more IC structures with a clock synchronization circuit using Gunn diodes, in accordance with various embodiments.

FIG. 10 is a side, cross-sectional view of an IC device that may include one or more IC structures with a clock synchronization circuit using Gunn diodes, in accordance with various embodiments.

FIG. 11 is a side, cross-sectional view of an IC package that may include one or more IC structures with a clock synchronization circuit using Gunn diodes, in accordance with various embodiments.

FIG. 12 illustrates a cross-sectional side view of an IC device assembly that may include one or more IC structures with a clock synchronization circuit using Gunn diodes, in accordance with various embodiments.

FIG. 13 is a block diagram of an example computing device that may include one or more IC structures with a clock synchronization circuit using Gunn diodes, in accordance with various embodiments.

FIG. 14 is a block diagram of an example processing device that may include one or more IC structures with a clock synchronization circuit using Gunn diodes, in accordance with various embodiments.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

A diode is a two-terminal device that conducts current in one direction, referred to as the forward direction, while generally blocking current in the opposite direction, referred to as the reverse direction. In the forward direction, current enters through one terminal, which is called the anode, and leaves through the other terminal, which is called the cathode. When at least a minimum voltage, referred to as a forward voltage, is applied to the anode, this turns on the diode and current flows across the diode in the forward direction, from the anode to the cathode. Different types of materials may be used to form a diode. Many semiconductor diodes include a p-n junction, which is an interface between two types of semiconductor materials, p-type and n-type. Semiconductor diodes may include silicon, germanium, or other types of semiconductor materials.

Gunn diodes do not include a p-n junction. Instead, Gunn diodes include a stack of n-doped materials, with two highly doped regions (referred to as doped regions or n+ regions) near the terminals, and a lightly doped region (referred to as an n region, active region, or buffer region) between the highly doped regions. In a Gunn diode, one of the n+ regions may be larger than the other, with the current traveling through the larger n+ region, through the n region, and then though the smaller n+ region. The larger n+ region may advantageously provide good ohmic contact and low contact resistance with the anode, which may help ensure efficient carrier injection and provide proper electric field distribution through the device.

In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with holes as the primary charge carrier is referred to as p-type, and a semiconductor material or semiconductor region with electrons as the primary charge carrier is referred to as n-type. The oscillation effect of a Gunn diode is exhibited in stacks of n-type materials with electron charge carriers.

When a voltage is applied across the lightly n-doped active region, an electric field develops across the active region. Initially, current across the device increases, but after reaching the threshold voltage, the Gunn diode operates in a negative differential resistance region in which the current decreases. After a current pulse exits the device, another pulse is generated by again increasing the voltage. The series of current pulses produces a sustained oscillation at an oscillation frequency, where the frequency may be based on device characteristics, such as thickness of the active region and operating temperature.

In the past, Gunn diodes have been used as oscillators for various applications, such as radio frequency (RF) communications, microwave transmitters, military radar, and various sensors. Embodiments of the present disclosure are based on recognition that recent developments in semiconductor manufacturing may allow manufacturing Gunn diodes in a single IC structure with transistors (e.g., FinFETs or nanoribbon/nanowire transistors) and that, as a result, oscillations produced by Gunn diodes may be used to realize IC clock synchronization circuits that may have advantages over conventional implementations of clock synchronization devices. Generally, clock synchronization circuits in electronic devices are circuits designed to ensure that different components of a system operate in sync with each other. This synchronization is crucial for the proper functioning of digital systems, especially in complex integrated circuits like microprocessors, memory modules, and communication systems. The primary purpose of clock synchronization is to ensure that all parts of the system share a common time reference, which is essential for data transfer, processing, and overall system stability. To that end, a clock synchronization circuit is designed to provide a clock signal to be distributed throughout the system, e.g., throughout an IC structure or a larger IC device including such an IC structure, where a clock signal is a continuous, oscillating signal used to coordinate the actions of electronic components. In this manner, a clock signal can serves as a timing reference for sequential operations.

Embodiments of the present disclosure may improve on at least some of the challenges and issues described above by providing a clock synchronization circuit that includes a first transistor, a second transistor, a first Gunn diode coupled to the first transistor, a second Gunn diode coupled to the second transistor, and a third transistor coupled between the first Gunn diode and the second Gunn diode. First, second, and third transistors coupled to the first and second Gunn diodes form two cross-coupled inverters, where the third transistor may be seen as providing the coupling. The third transistor may be used to control coupling between the first Gunn diode and the second Gunn diode, as well as to control the phase of the coupling. If one inverter output is high, it drives the input of the other inverter low, and vice versa, thus creating a stable oscillating signal that may be used as a clock signal for synchronizing operation of various components of an IC device.

The Gunn diodes described herein may advantageously be used in low-temperature environments, such as cooled IC devices. In general, operating semiconductor devices at lower temperatures may improve their performance. For example, lower temperatures can lead to increased drive currents across transistors, and transistors operating at lower temperatures generally experience lower leakage. In Gunn diodes, a lower temperature leads to a steeper and longer negative differential range, which can improve performance and stability of the Gunn diodes described herein.

In the following detailed description, various aspects of the illustrative implementations may be described using terms commonly employed by those skilled in the art to convey the substance of their work to others skilled in the art. For example, the term “connected” means a direct electrical connection between the things that are connected (e.g., with the things being in electrically conductive and/or physical contact, e.g., in direct contact or directly electrical connected), without any intermediary devices, while the term “coupled” means either a direct electrical connection between the things that are connected, or an indirect connection through one or more passive or active intermediary devices. Describing A and B are being “in contact” includes A and B being in direct physical contact, possibly with an interface that may form when A and B are brough into direct physical contact with one another. The term “circuit” means one or more passive and/or active components that are arranged to cooperate with one another to provide a desired function. The terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulator material” may refer to solid materials (and/or liquid materials that solidify after processing as described herein) that are substantially electrically non-conducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting/conductive” can also mean “optically conducting/conductive. ”

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

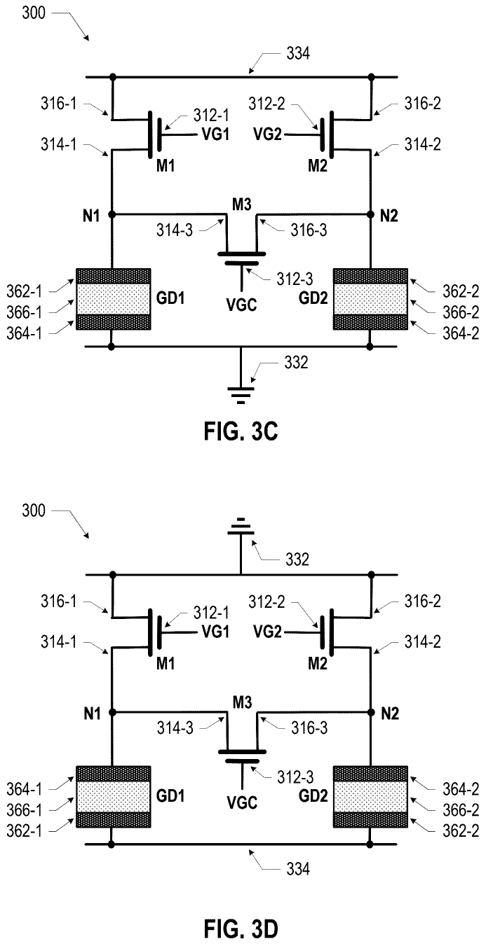

Any of the features discussed with reference to any of accompanying drawings herein may be combined with any other features to form IC structures with clock synchronization circuits using Gunn diodes, as appropriate. A number of elements of the drawings are shared with others of the drawings; for ease of discussion, a description of these elements is not repeated, and these elements may take the form of any of the embodiments disclosed herein. For convenience, a collection of drawings labeled with letters may be referred to without letters (e.g., a collection of drawings shown in FIGS. 3A-3H may be referred to as FIG. 3).

The drawings are not necessarily to scale. In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with clock synchronization circuits using Gunn diodes as described herein.

Various IC structures with clock synchronization circuits using Gunn diodes as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

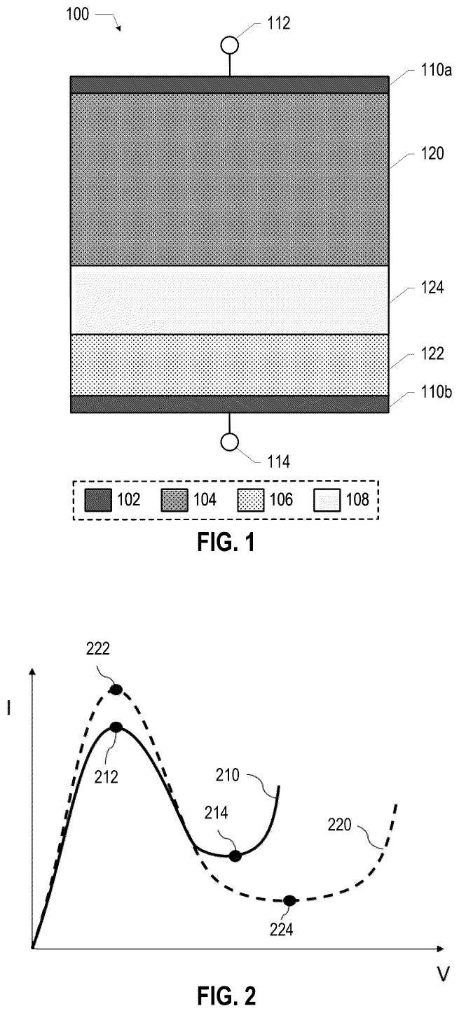

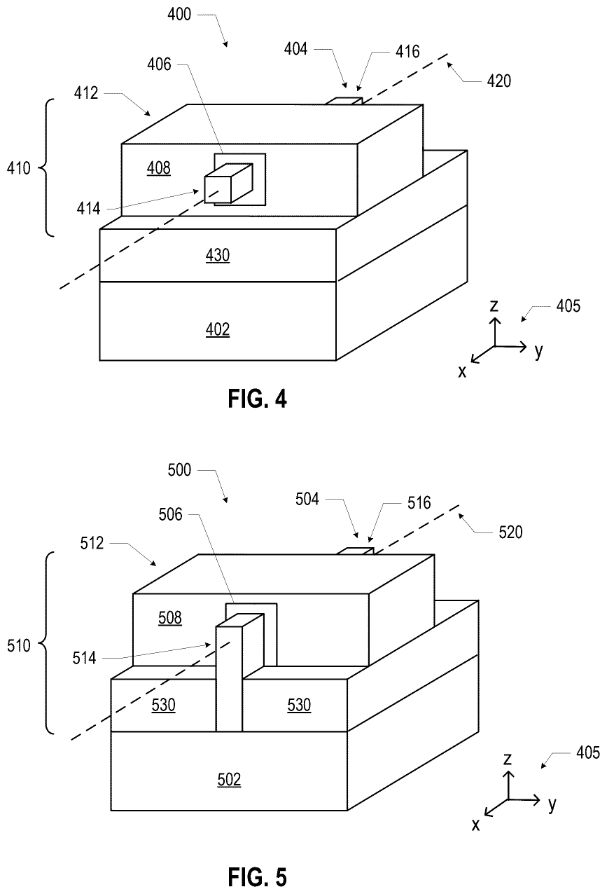

FIG. 1 illustrates a cross-section of an IC structure with a Gunn diode 100, also referred to as a diode 100, according to some embodiments of the present disclosure. The diode 100 may be included in a clock synchronization circuit, e.g., as shown in FIGS. 3A-3H, and may be implemented in an IC structure implementing such clock synchronization circuit, e.g., as shown in FIGS. 6A-6B, FIGS. 7A-7D, and FIGS. 8A-8H. A number of elements referred to in the description of some of the present drawings with reference numerals are illustrated in these figures with different patterns, with a legend showing the correspondence between the reference numerals and patterns being provided at the bottom of the drawing pages. For example, the legend in FIG. 1 illustrates that FIG. 1 uses different patterns to show a conductor 102, a first n+ material 104, a second n+ material 106, and an active material 108.

As shown in FIG. 1, the diode 100 may include two layers 110a and 110b of the conductor 102, a first n+ region 120 of the first n+ material 104, a second n+ region 122 of the second n+ material 106, and an active region 124 of the active material 108. The layers 110a and 110b may be generally referred to as metal layers, and the regions 120, 122, and 124 may be generally referred to as semiconductor layers. The terminals 112 and 114 are represented on the metal layers 110a and 110b; in this case, the terminal 112 is the anode, and the terminal 114 is the cathode. The forward direction of the current flow, from the terminal 112 (anode) to the terminal 114 (cathode), is indicated by the arrow labelled I.

The active region 124 may have a thickness or height, measured in the z-direction, on the order of 1 nanometers or 10 nanometers. For example, the active region 124 may have a thickness between 1 nanometer and 100 nanometers, between 1 nanometer and 10 nanometers, between 10 nanometers and 40 nanometers, or in another range. The thickness of the active region 124 may be based at least in part on the bandgap of the active material, e.g., a high-bandgap material may have a smaller thickness (e.g., less than 10 nanometers). Each of the n+ regions 120 and 122 may also have a thickness on the order of 10 nanometers, e.g., between 10 nanometers and 100 nanometers, between 15 nanometers and 50 nanometers, between 20 nanometers and 40 nanometers, or within some other range.

The conductor 102 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the conductor 102 may include one or more electrically conductive alloys, oxides, or carbides of one or more metals.

One or more of the materials 104, 106, and 108 may include a monocrystalline semiconductor, such as silicon or germanium. For example, the active material 108 may be formed from a silicon wafer, and the n+ materials 104 and 106 are more highly doped regions of the wafer and/or doped silicon that has been epitaxially deposited.

In some embodiments, one or more of the semiconductor materials may include a compound semiconductor with a first sub-lattice of at least one element from group III of the periodic table (e.g., Al, Ga, In), and a second sub-lattice of at least one element of group V of the periodic table (e.g., P, As, Sb). For some embodiments, one or more of the semiconductor materials may include a III-V material having a high electron mobility, such as, but not limited to InGaAs, InP, InSb, and InAs. For some such embodiments, one or more of the semiconductor materials may be a ternary III-V alloy, such as InGaAs, GaAsSb, InAsP, or InPSb. For some InₓGa₁₋ₓAs embodiments, the In content (x) may be between 0.6 and 0.9, and may advantageously be at least 0.7 (e.g., In_{0.7}Ga_{0.3}As). For other embodiments, one or more of the semiconductor materials may be a group IV material having a high hole mobility, such as, but not limited to Ge or a Ge-rich SiGe alloy. For some example embodiments, one or more of the semiconductor materials may have a Ge content between 0.6 and 0.9, and may be at least 0.7.

In some embodiments, the active material 108 and/or n+ materials 106 and 108 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, one or more of the semiconductor materials may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, n-type amorphous or polycrystalline silicon, germanium, indium gallium arsenide, silicon germanium, gallium nitride, aluminum gallium nitride, indium phosphite, and black phosphorus.

In some embodiments, the active material 108 and/or n+ materials 106 and 108 include silicon and carbon (e.g., silicon carbide). In some embodiments, the active material 108 and/or n+ materials 106 and 108 include tungsten combined with one or more of nitrogen, selenium, and sulfur (e.g., tungsten nitride, tungsten diselenide, or tungsten disulfide), or molybdenum combined with one or more of nitrogen, selenium, and sulfur (e.g., molybdenum nitride, molybdenum diselenide, or molybdenum disulfide).

At least a portion of the n+ regions 120 and 122 may be formed using epitaxial growth. In general, epitaxial growth involves crystal growth or material deposition in which crystalline layers are grown over an existing crystalline structure, where the grown layers are formed with one or more well-defined orientations with respect to the underlying crystal structure. Epitaxial growth process may be particularly advantageous for forming Gunn diodes as it may be carefully controlled and can produce crystalline layers having a minimal amount of defects.

The materials 104, 106, and 108 of the first n+ region 120, second n+ region 122, and active region 124, respectively, may be selected such that the active region 124 has a lower dopant concentration than the first n+ region 120 and second n+ region 122. The first n+ region 120, second n+ region 122, and active region 124 all have the same charge carrier, i.e., n-type charge carriers. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with electrons as the primary charge carrier is referred to as n-type. Doping may be used to create an n-type material; for example, silicon can be doped with another element such that the resulting doped material is n-type. Dopants added to a semiconductor material to make it n-type may be referred to as n-type dopants. Suitable n-type dopants for one or more of the materials 104, 106, and 108 may include phosphorus, arsenic, antimony, phosphorous, tellurium, sulfur, tin, silicon, germanium, etc.

In general, the active material 108 may have a relatively low level of dopants, e.g., a lower dopant concentration than the first n+ material 104 and the second n+ material 106. For example, the first n+ material 104 may be a highly-doped n-type material, the active material 108 may be a lower-doped n-type material, and the second n+ material 106 may be a highly-doped n-type material. The active material 108 may have a dopant concentration on the order of 10¹⁶ to 10¹⁸ dopants per cubic centimeter (cm⁻³). The first n+ material 104 and second n+ material 106 may each have a dopant concentration on the order of 10¹⁸ to 10²⁴ cm⁻³. In some embodiments, the dopant concentration of the n+ materials 104 and 106 may be at least ten times greater, at least 100 times greater, or at least 1000 times greater than the dopant concentration of the active material 108. In some embodiments, different dopants (e.g., different ones of the phosphorus, arsenic, antimony, etc.) may be included in different ones of the materials 104, 106, and 108. In some embodiments, the active material 108 may have the same dopant as the first n+ material 104 and/or the second n+ material 106, but at a lower concentration. Furthermore, the base material (e.g., silicon, germanium, etc.) for each of these regions may be the same or different. In some embodiments, the active material 108 may have a wider bandgap than the n+ materials 104 and 106.

In some embodiments, the n+ regions 120 and 122 may have different dopant concentrations. The thicknesses selected for the n+ regions 120 and 122 (where the thicknesses may be dimensions of the diode 100 measured along the vertical direction of the illustration of FIG. 1) may be inversely related to the dopant concentrations of the n+ regions 120 and 122. At the terminal 112 (anode), a relatively large collector may have a relatively low dopant concentration, and at the terminal 114 (cathode), a relatively small emitter may have a relatively high dopant concentration. For example, the first n+ region 120, which is larger (as shown in FIG. 1), may have a lower dopant concentration than the second n+ region 122, which is smaller.

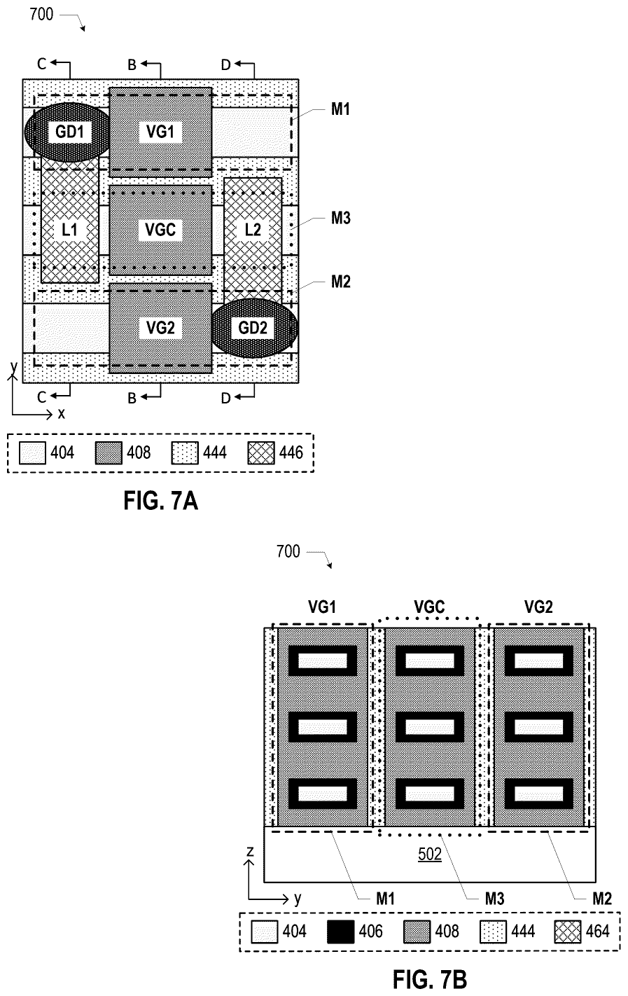

In some embodiments, the Gunn diode 100 may extend vertically through a layer of an IC structure (e.g., through a device layer or a metal layer, as described with reference to FIGS. 8A-8H), where the metal layer 110a is a first contact (e.g., a front-side contact) on one side of the layer of an IC structure, and the metal layer 110b is a second contact (e.g., a back-side contact) on the opposite side of the layer of an IC structure. An array of multiple similar diodes may be formed across a layer of an IC structure. In some other embodiments, the Gunn diode 100 may be oriented horizontally, with the active region 124 arranged horizontally between the first n+ region 120 and second n+ region 122.

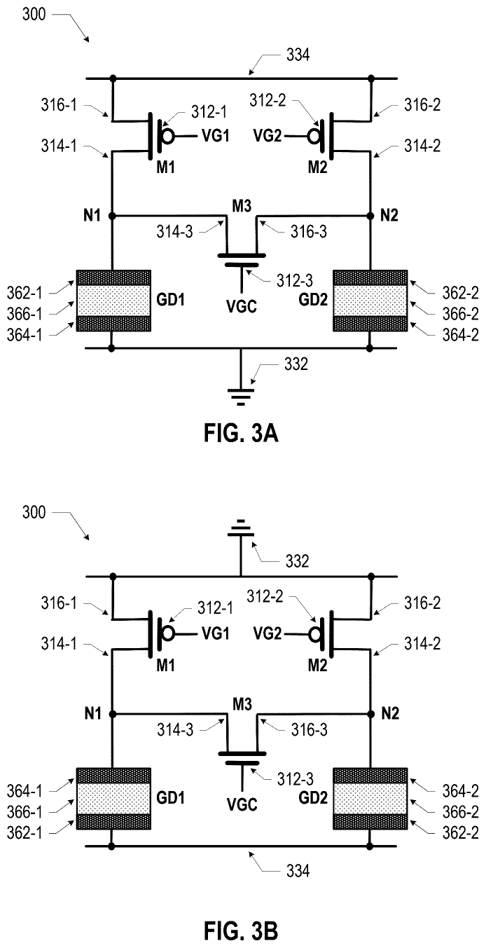

FIG. 2 illustrates example I-V curves for the Gunn diodes disclosed herein. FIG. 2 illustrates voltage V along the horizontal axis and current I along the vertical axis. FIG. 2 includes two example I-V curves 210 and 220 of a Gunn diode at different operating temperatures. The Gunn diode has a negative differential resistance region. In general, in a negative differential resistance device, voltage is a single valued function of the current, but the current is a multivalued function of the voltage. Turning first to the curve 210, the negative resistance region for this curve 210 is between the points 212 and 214; in this portion of the curve 210, the current decreases as the voltage increases. The voltage at the point 212 is a threshold voltage Vₜₕ for the Gunn diode. When the voltage difference across the Gunn diode increases beyond Vₜₕ, the current density starts to decrease. The current further decreases with an increase in the applied voltage. In this region, the device exhibits negative resistance.

When the current pulse enters the active layer (e.g., the active region 124), the voltage difference across the active layer decreases. This prevents another current pulse from passing through the device until the previous current pulse passes through the other end (e.g., through the cathode 114). The voltage difference across the device then rises again, and another pulse begins traversing the active layer. The current continues pulsing in this manner, producing an oscillation at a particular oscillating frequency. If the voltage were further increased, beyond the point 214, which is referred to as the valley voltage or valley point, the current starts increasing again, and the device again exhibits positive resistance.

The curve 210 represents device operation at a first temperature. The second curve 220 represents device operation of the same device at a second temperature that is lower than the first temperature. For example, the curve 210 may characterize a device at 300 Kelvin, and the curve 220 may characterize the same device at 100 Kelvin. The negative resistance region for the curve 220 is between the points 222 and 224, where the voltage of the point 222 is the threshold voltage Vₜₕ, and the voltage at the point 224 is the valley voltage.

In this example, the threshold voltages of the curves 210 and 220 are the same or substantially the same; in some embodiments, the threshold voltages of the two curves 210 and 220 may be different. The peak current at the threshold voltage of the curve 220 may be higher than the peak current at the threshold voltage of the curve 210. In addition, the valley voltage of the curve 220 may be higher than the valley voltage of the curve 210, and the current at the valley point 224 may be lower than the current at the valley point 214. Furthermore, the curve 210 may decrease more sharply or steeply than the curve 220. A Gunn diode may have improved performance at lower temperatures (e.g., at the lower temperature of the second curve 220) as represented by the exaggerated shape of the curve 220 compared to the curve 210.

FIGS. 3A-3H are electric circuit diagrams of example clock synchronization circuits 300 with Gunn diodes, according to some embodiments of the present disclosure.

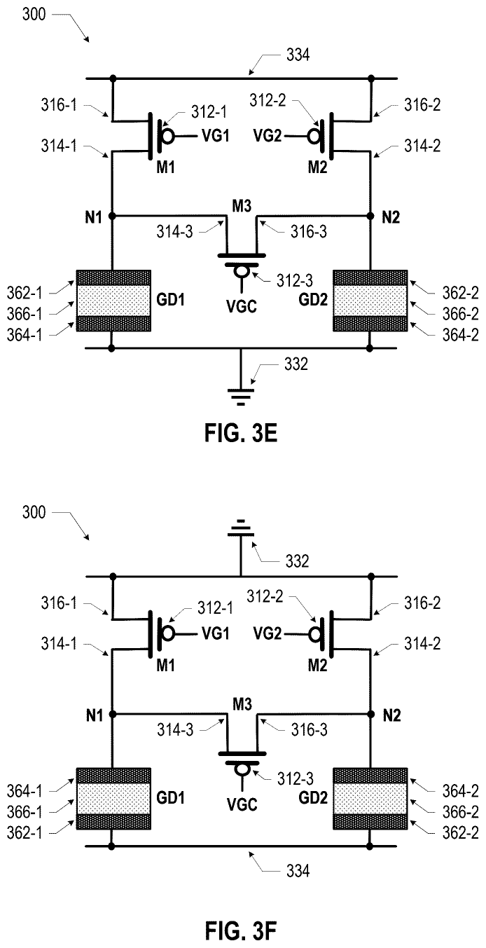

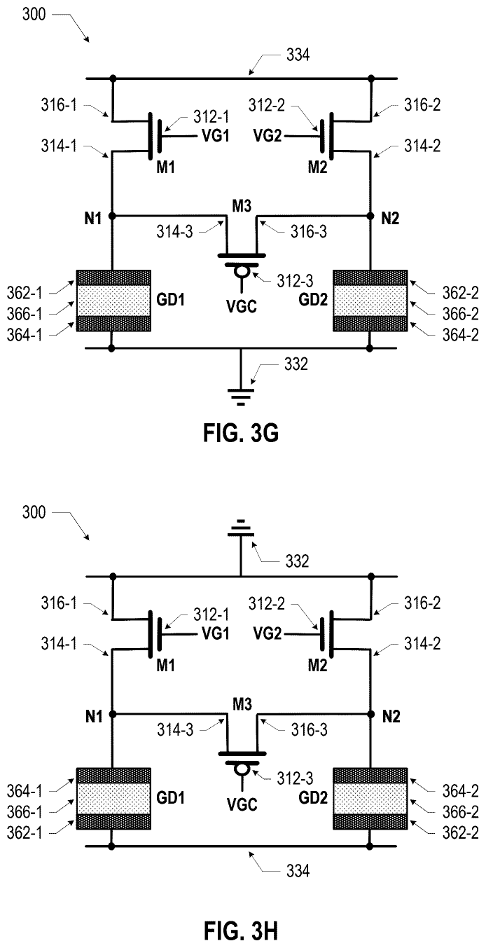

As shown in FIGS. 3A-3H, each of the clock synchronization circuits 300 includes transistors M1, M2, and M3. Each of the transistors M1-M3 may be a field-effect transistor (FET), e.g., a metal-oxide-semiconductor (MOS) FET (MOSFET), of any transistor architecture (e.g., planar or non-planar, FinFET, nanoribbon/nanowire, etc.). Two example transistors that may be used to implement any of the transistors M1-M3 are shown in FIG. 4 and FIG. 5. As a FET, each of the transistors M1-M3 includes a gate 312, a first S/D region 314, and a second S/D region 316 (e.g., the first S/D region 314 may be a source region and the second S/D region 316 may be a drain region, or vice versa), where the gate 312, the first S/D region 314, and the second S/D region 316 of different transistors are denoted in FIGS. 3A-3H with different reference numerals after the dash, the reference numerals being the same as in one of the transistors M1-M3. For example, the transistor M2 includes a gate 312-2, a first S/D region 314-2, and a second S/D region 316-2, while the transistor M3 includes a gate 312-3, a first S/D region 314-3, and a second S/D region 316-3.

As also shown in FIGS. 3A-3H, each of the clock synchronization circuits 300 further includes Gunn diodes GD1 and GD2. Each of the Gunn diodes GD1-GD2 may include a first electrode 362, a second electrode 364, and a Gunn diode stack 366, where the first electrode 362, the second electrode 364, and the Gunn diode stack 366 of different Gunn diodes are denoted in FIGS. 3A-3H with different reference numerals after the dash, the reference numerals being the same as in one of the Gunn diodes GD1-GD2. For example, the Gunn diode GD1 includes a first electrode 362-1, a second electrode 364-1, and a Gunn diode stack 366-1, while the Gunn diode GD2 includes a first electrode 362-2, a second electrode 364-2, and a Gunn diode stack 366-2. Each of the Gunn diodes GD1-GD2 may be the Gunn diode 100 as described above and may be implemented in an IC structure in any suitable geometry, e.g., either by extending vertically or extending horizontally through a layer of an IC structure. When the Gunn diodes GD1-GD2 are implemented as the Gunn diode 100, the first electrode 362 may be the layer 110a of the conductor 102, connected to the terminal 112 (anode), and the second electrode 364 may be the layer 110b of the conductor 102, connected to the terminal 114 (cathode). Furthermore, the Gunn diode stack 366 may then be a stack of the first n+ region 120 of the first n+ material 104, the active region 124 of the active material 108, and the second n+ region 122 of the second n+ material 106, arranged between the first electrode 362 and the second electrode 364 as described above.

For each of the clock synchronization circuits 300, the first S/D region 314-1 of the transistor M1 is coupled (e.g., directly electrically connected) to one of the two electrodes of the Gunn diode GD1 and to the first S/D region 314-3 of the transistor M3 at what is labeled in FIGS. 3A-3H as a node N1 (shown with a dot), while the first S/D region 314-2 of the transistor M2 is coupled (e.g., directly electrically connected) to one of the two electrodes of the Gunn diode GD2 and to the second S/D region 316-3 of the transistor M3 at what is labeled in FIGS. 3A-3H as a node N2 (also shown with a dot). Thus, the transistor M3 is a coupling transistor configured to couple the Gunn diodes GD1 and GD2. Also for each of the clock synchronization circuits 300, the gate 312-1 of the transistor M1 is coupled to a gate voltage VG1, the gate 312-2 of the transistor M2 is coupled to a gate voltage VG2, and the gate 312-3 of the transistor M3 may be coupled to a gate voltage VGC (where “C” stands for “coupling” because the transistor M3 couples the Gunn diodes GD1 and GD2).

Each of the lines shown in FIGS. 3A-3H represent electrical connections in the form of interconnects such as conductive lines and conductive vias between various terminals of the transistors M1-M3 and the Gunn diodes GD1-GD2, and from some of these terminals to a ground voltage 332 and to a supply voltage 334. Any of the interconnects of the clock synchronization circuits 300 may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

Where the different embodiments of FIGS. 3A-3H differ is in whether it is the Gunn diodes GD1 and GD2 or the transistors M1-M2 that are closer to the ground voltage 332 than to the supply voltage 334, and whether the transistors M1-M2 are n-type metal-oxide-semiconductor (NMOS) or P-type metal-oxide-semiconductor (PMOS) transistors. In general, the transistor M3 may be either NMOS or PMOS, irrespective of whether the transistors M1-M2 are NMOS or PMOS. Thus, eight different embodiments are possible.

FIG. 3A illustrates an embodiment where it is the Gunn diodes GD1 and GD2, and not the transistors M1-M2, that are closer to the ground voltage 332 than to the supply voltage 334. Since typically it is a cathode terminal of a diode that is connected to the ground voltage, as shown in FIG. 3A, the second electrode 364-1 of the Gunn diode GD1 and the second electrode 364-2 of the Gunn diode GD2 are coupled (e.g., directly electrically connected) to one another and to the ground voltage 332. In such an embodiment, the first electrode 362-1 of the Gunn diode GD1 is coupled (e.g., directly electrically connected) to the first S/D region 314-1 of the transistor M1 and to the first S/D region 314-3 of the transistor M3, the first electrode 362-2 of the Gunn diode GD2 is coupled (e.g., directly electrically connected) to the first S/D region 314-2 of the transistor M2 and to the second S/D region 316-3 of the transistor M3, and the second S/D region 316-1 of the transistor M1 and the second S/D region 316-2 of the transistor M2 are coupled (e.g., directly electrically connected) to one another and to the supply voltage 334. In the embodiment of FIG. 3A, the transistors M1-M2 are PMOS transistors and the transistor M3 is an NMOS transistor.

FIG. 3B illustrates an embodiment where it is the transistors M1-M2, and not the Gunn diodes GD1 and GD2, that are closer to the ground voltage 332 than to the supply voltage 334, which means that the ground voltage 332 and the supply voltage 334 are swapped in FIG. 3B, compared to FIG. 3A. To make the cathode terminals of the Gunn diodes GD1 and GD2 closer to the ground voltage 332 than to the supply voltage 334, this means that the designation of the first electrodes 362 and the second electrodes 364 of the Gunn diodes GD1 and GD2 are also swapped in FIG. 3B, compared to FIG. 3A. Thus, in such an embodiment, as shown in FIG. 3B, the first electrode 362-1 of the Gunn diode GD1 and the first electrode 362-2 of the Gunn diode GD2 are coupled (e.g., directly electrically connected) to one another and to the supply voltage 334.

Furthermore, the second electrode 364-1 of the Gunn diode GD1 is coupled (e.g., directly electrically connected) to the first S/D region 314-1 of the transistor M1 and to the first S/D region 314-3 of the transistor M3, the second electrode 364-2 of the Gunn diode GD2 is coupled (e.g., directly electrically connected) to the first S/D region 314-2 of the transistor M2 and to the second S/D region 316-3 of the transistor M3, and the second S/D region 316-1 of the transistor M1 and the second S/D region 316-2 of the transistor M2 are coupled (e.g., directly electrically connected) to one another and to the ground voltage 332. In the embodiment of FIG. 3B, the transistors M1-M2 are PMOS transistors and the transistor M3 is an NMOS transistor, the same as in the embodiment of FIG. 3A.

FIG. 3C illustrates an embodiment similar to that of FIG. 3A, except that the transistors M1-M2 are NMOS transistors in FIG. 3C. In the embodiment of FIG. 3C, the transistor M3 is an NMOS transistor as in FIG. 3A, and all of the connections remain the same as described for FIG. 3A.

FIG. 3D illustrates an embodiment similar to that of FIG. 3B, except that the transistors M1-M2 are NMOS transistors in FIG. 3D. In the embodiment of FIG. 3D, the transistor M3 is an NMOS transistor as in FIG. 3A, and all of the connections remain the same as described for FIG. 3B.

FIG. 3E illustrates an embodiment similar to that of FIG. 3A, except that the transistor M3 is a PMOS transistor in FIG. 3E. In the embodiment of FIG. 3E, the transistors M1-M2 are PMOS transistors as in FIG. 3A, and all of the connections remain the same as described for FIG. 3A.

FIG. 3F illustrates an embodiment similar to that of FIG. 3B, except that the transistor M3 is a PMOS transistor in FIG. 3F. In the embodiment of FIG. 3F, the transistors M1-M2 are PMOS transistors as in FIG. 3B, and all of the connections remain the same as described for FIG. 3B.

FIG. 3G illustrates an embodiment similar to that of FIG. 3C, except that the transistor M3 is a PMOS transistor in FIG. 3G. In the embodiment of FIG. 3G, the transistors M1-M2 are NMOS transistors as in FIG. 3C, and all of the connections remain the same as in FIG. 3C and, therefore, the same as described for FIG. 3A.

FIG. 3F illustrates an embodiment similar to that of FIG. 3D, except that the transistor M3 is a PMOS transistor in FIG. 3F. In the embodiment of FIG. 3F, the transistors M1-M2 are NMOS transistors as in FIG. 3D, and all of the connections remain the same as in FIG. 3D and, therefore, the same as described for FIG. 3B.

The three transistors M1-M3 and the two Gunn diodes GD1-GD2 in the illustrated configurations of the clock synchronization circuits 300 as shown in FIGS. 3A-3H form a stable circuit that may be used either for providing an output clock signal synchronized with an input clock signal or for generating a clock signal. When any of the clock synchronization circuits 300 is used for providing an output clock signal synchronized with an input clock signal, an input reference signal may be provided as the input clock signal at either the node N1 or at the node N2. Consider that the input clock signal is provided at the node N1. In this case, because the three transistors M1-M3 and the two Gunn diodes GD1-GD2 of the clock synchronization circuits 300 form two cross-coupled inverters, the output clock signal is then generated and output at the node N2, where the output clock signal is synchronized in frequency to the input clock signal provided at the node N1, and the phase difference between the output clock signal and the input clock signal is controlled by the voltage VGC applied to the gate 312-3 of the transistor M3. In various embodiments, the output clock signal may be completely in phase with the input clock signal (i.e., the phase difference between the output clock signal and the input clock signal is 0 degrees), or the output clock signal may be completely out of phase with the input clock signal (i.e., the phase difference between the output clock signal and the input clock signal is 180 degrees), or the phase of the output clock signal may be somewhere in between being in phase and out of phase with respect to the input clock signal (i.e., the phase difference between the output clock signal and the input clock signal is greater than 0 degrees but smaller than 180 degrees), depending on the voltage VGC applied to the gate 312-3 of the transistor M3. When any of the clock synchronization circuits 300 is used for generating a clock signal, no input clock signals are provided at nodes N1 and N2. Instead, by virtue of providing a voltage at the supply voltage 334, the clock synchronization circuits 300 will generate oscillating signals, where one of the oscillating signals will appear at the node N1 and the other one of the oscillating signals will appear at the node N2, with frequencies of these two oscillating signals being substantially the same, and the phase between them being controlled by the voltage VGC applied to the gate 312-3 of the transistor M3. Either one or both of the oscillating signals appearing at the nodes N1 and N2 may then be used as a clock signal for synchronizing operation of components in an IC structure/device.

As mentioned above, each of the transistors M1-M3 may be a FET of any transistor architecture. A FET is a three-terminal device that includes source, drain, and gate terminals and uses electric field to control current flowing through the device. A FET typically includes a semiconductor channel material, a source region and a drain region provided in the channel material, and a gate stack that includes at least a gate electrode material and, optionally, may also include a gate insulator, where the gate stack is provided over a portion of the channel material between the source region and the drain region.

Recently, FETs with non-planar architectures, such as FinFETs (also sometimes referred to as “wrap around gate transistors” or “tri-gate transistors”) and nanoribbon/nanowire transistors (also sometimes referred to as “gate all-around (GAA) transistors”), have been extensively explored as alternatives to transistors with planar architectures.

In a FinFET, an elongated semiconductor structure (i.e., an elongated structure that includes a semiconductor material) shaped as a fin extends away from a base (e.g., from a semiconductor substrate or any suitable support structure). A portion of a fin that is closest to the base may be enclosed by an insulator material. Such an insulator material, typically an oxide, is commonly referred to as a “shallow trench isolation” (STI), and the portion of the fin enclosed by the STI is referred to as a “subfin portion” or simply a “subfin. ” A gate stack may wrap around an upper portion of the fin (i.e., the portion farthest away from the base). The portion of the fin around which the gate stack wraps is referred to as a “channel” or a “channel portion” of a FinFET. A semiconductor material of the channel portion is commonly referred to as a “channel material” of the transistor. FinFETs are sometimes referred to as “tri-gate transistors” because, in use, such transistors may form conducting channels on three “sides” of the channel portion of the fin. A source region and a drain region are provided in the fin on the opposite sides of the gate stack, forming, respectively, a source and a drain of a FinFET.

In a nanoribbon transistor, a gate stack may be provided around a portion of an elongated semiconductor structure called “nanoribbon”, forming a gate on all sides of the nanoribbon. The “channel” or the “channel portion” of a nanoribbon transistor is the portion of the nanoribbon around which the gate stack wraps. Such transistors are sometimes referred to as “GAA transistors” because, in use, such transistors may form conducting channels on all “sides” of the channel portion of the nanoribbon. A source region and a drain region are provided in the nanoribbon on each side of the gate stack, forming, respectively, a source and a drain of a nanoribbon transistor. In some settings, the term “nanoribbon” has been used to describe an elongated semiconductor structure that has a substantially rectangular transverse cross-section (i.e., a cross-section in a plane perpendicular to the longitudinal axis of the structure), while the term “nanowire” has been used to describe a similar structure but with a substantially circular or square transverse cross-sections. In the following, a single term “nanoribbon transistor” is used to describe all non-planar transistors where a gate stack wraps around substantially all sides of an elongated semiconductor structure, independent of the shape of the transverse cross-section. Thus, as used herein, the term “nanoribbon transistor” is used to cover transistors with elongated semiconductor structures that have substantially rectangular transverse cross-sections (possibly with rounded corners), transistors with elongated semiconductor structures that have substantially square transverse cross-sections (possibly with rounded corners), transistors with elongated semiconductor structures that have substantially circular or elliptical/oval transverse cross-sections, as well as transistors with elongated semiconductor structures that have any polygonal transverse cross-sections.

As the foregoing illustrates, both FinFETs and nanoribbon transistors are built based on elongated semiconductor structures. A longitudinal axis of such structures may be defined as a line that is the shortest line between a source region and a drain region of a FinFET or a nanoribbon transistor. Such a line may extend substantially parallel to a support structure (e.g., a die, a chip, a substrate, a carrier substrate, or a package substrate) on/in which a transistor resides and may be one of lines of symmetry for the transistor (at least for the idealized version of the transistor that does not reflect unintended manufacturing variations that may affect the real-life geometry of the transistor).

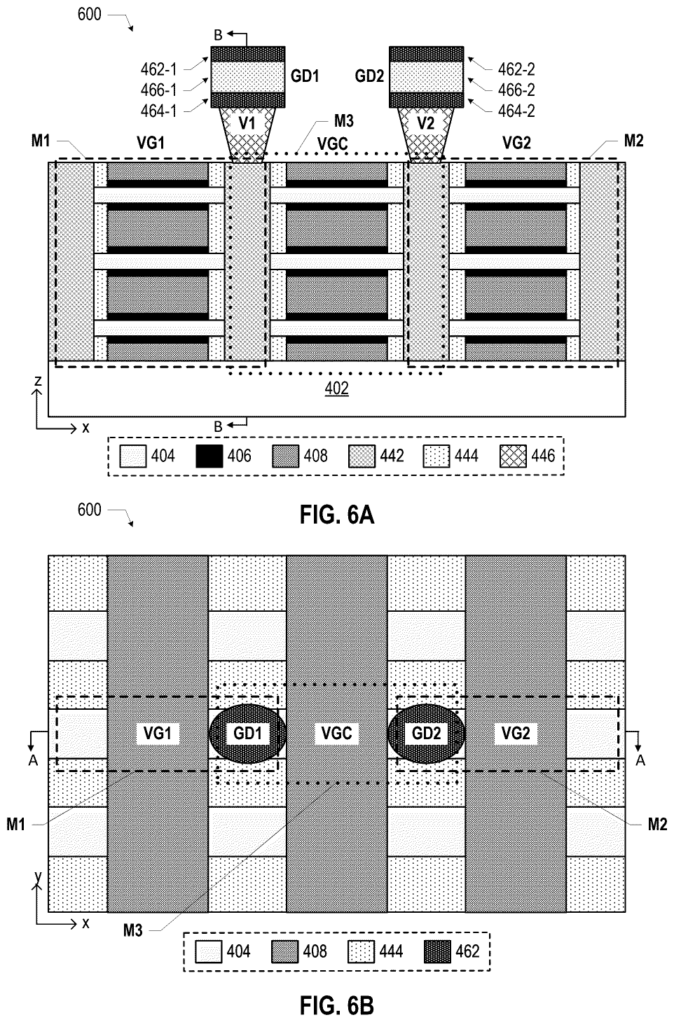

FIG. 4 provides a perspective view of an example IC structure 400 implementing a nanoribbon transistor 410 that may be included in a clock synchronization circuit with Gunn diodes, in accordance with some embodiments. The nanoribbon transistor 410 is one example of how any of the transistors M1-M3 of the clock synchronization circuits 300 may be implemented in various IC structures and assemblies described herein. FIG. 4 is a perspective drawing and an example coordinate system 405 (x-y-z coordinate system) is shown there to assist explanations. The coordinate system 405 is also shown in FIG. 5, and other drawings illustrating various axes (e.g., FIGS. 6A-6B, FIGS. 7A-7D) refer to the axes of the coordinate system 405.

Turning to the details of FIG. 4, the IC structure 400 may include a semiconductor material, which may include one or more semiconductor materials, formed as a nanoribbon 404 (i.e., an elongated semiconductor structure) extending substantially parallel to a support 402. The transistor 410 may be formed on the basis of the nanoribbon 404 by providing a gate stack 412 at least partially wrapping around a portion of the nanoribbon referred to as a “channel portion” and by providing S/D regions, shown in FIG. 4 as a first S/D region 414 and a second S/D region 416, on either side of the gate stack 412. In some embodiments, a layer of oxide material 430 may be provided between the support 402 and the gate stack 412/the nanoribbon 404. Although only a single nanoribbon 404 is shown in FIG. 4, in some embodiments, the IC structure 400 may include a stack of nanoribbons 404, where nanoribbons 404 are vertically stacked above one another, as known in the art. In such embodiments, the gate stack 412 may at least partially wrap around portions of multiple (e.g., all) nanoribbons 404 of the stack, and each of the first S/D region 414 and the second S/D region 416 may extend continuously throughout the stack, thus forming a single transistor 410 with channel portions in multiple nanoribbons 404 of the stack. Some example implementations of transistors formed based on stacks of nanoribbons are shown in FIGS. 6A-6B and FIGS. 7A-7D.

The IC structure 400 shown in FIG. 4, as well as IC structures/devices shown in other drawings of the present disclosure, is intended to show relative arrangements of some of the components therein, and the IC structures/devices shown herein, or portions thereof, may include other components that are not illustrated. For example, electrical contacts to the S/D regions 414 and 416 of the transistor 410, and additional layers such as a spacer layer around the gate stack 412 of the transistor 410, etc., are not shown in FIG. 4. In another example, although not specifically illustrated in FIG. 4, a dielectric spacer may be provided between a first S/D contact that may be coupled to a first S/D region 414 of the transistor 410 and the gate stack 412 as well as between a second S/D contact that may be coupled to a second S/D region 416 of the transistor 410 and the gate stack 412 in order to provide electrical isolation between the source, gate, and drain contacts (in general, “contacts” described herein may also be referred to as “electrodes”). In yet another example, although not specifically illustrated in FIG. 4, at least portions of the transistor 410 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 410 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

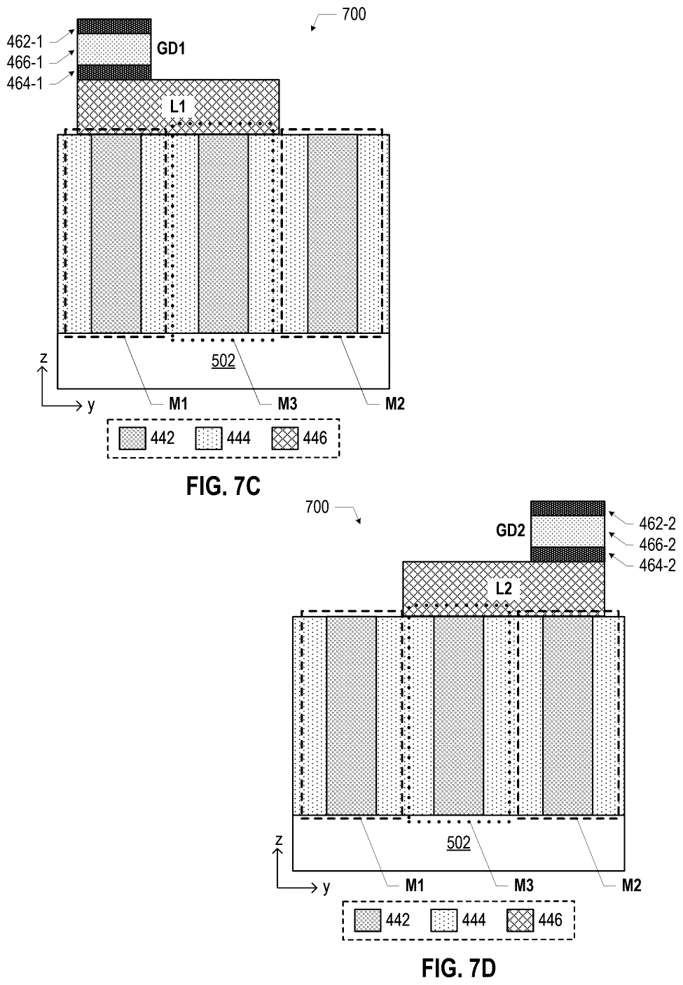

Implementations of the present disclosure may be formed or carried out on any suitable support 402, such as a substrate, a die, a wafer, or a chip. The support 402 may, e.g., be the wafer 2000 of FIG. 9, discussed below, and may be, or be included in, a die, e.g., the singulated die 2002 of FIG. 9, discussed below. The support 402 may be a semiconductor substrate composed of semiconductor material systems including, for example, n-type or P-type materials systems. In one implementation, the semiconductor substrate may be a crystalline substrate formed using a bulk silicon or a SOI substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 402 may be a printed circuit board (PCB) substrate. Although a few examples of materials from which the support 402 may be formed are described here, any material that may serve as a foundation upon which an IC structure with a clock synchronization circuit using Gunn diodes as described herein may be built falls within the spirit and scope of the present disclosure.

The nanoribbon 404 may take the form of a nanowire or nanoribbon, for example. In some embodiments, an area of a transverse cross-section of the nanoribbon 404 (i.e., an area in the y-z plane of the coordinate system 405) may be between about 25 and 10000 square nanometers, including all values and ranges therein (e.g., between about 25 and 1000 square nanometers, or between about 25 and 500 square nanometers). The transverse cross-section of the nanoribbon 404 is cross-section along a plane perpendicular to a longitudinal axis 420 of the nanoribbon 404, where the longitudinal axis 420 may, e.g., be along the x-axis of the coordinate system 405 and is shown in FIG. 4 with a dashed line. In some embodiments, a width of the nanoribbon 404 (i.e., a dimension measured in a plane parallel to the support 402 and in a direction perpendicular to the longitudinal axis 420, e.g., along the y-axis of the coordinate system 405) may be at least about 3 times larger than a thickness (or a “height”) of the nanoribbon 404 (i.e., a dimension measured in a plane perpendicular to the support 402, e.g., along the z-axis of the coordinate system 405), including all values and ranges therein, e.g., at least about 4 times larger, or at least about 5 times larger.

Although the nanoribbon 404 illustrated in FIG. 4 is shown as having a square cross-section, or, more generally, a rectangular cross-section, the nanoribbon 404 may instead have a cross-section that is rounded at corners or otherwise irregularly shaped, and the gate stack 412 may conform to the shape of the nanoribbon 404. The terms “front face” and “back face” of a nanoribbon may refer to the faces of the nanoribbon 404 that are substantially parallel to the support 402, the term “sidewall” (or “side face”) of a nanoribbon may refer to the opposing faces of the nanoribbon 404 that are substantially perpendicular to the support 402 and extend in a direction of the longitudinal axis 420 of the nanoribbon 404, while the term “end” of a nanoribbon may refer to the opposing faces of the nanoribbon 404 that are substantially perpendicular to the longitudinal axis 420 of the nanoribbon 404.

The nanoribbon 404 may be formed of one or more semiconductor materials, together referred to as a “channel material. ” In general, channel materials of any of the transistors described herein, e.g., the channel material of the transistor 410, may be composed of semiconductor material systems including, for example, n-type or P-type materials systems. In some embodiments, the channel material may include a substantially monocrystalline semiconductor, such as silicon (Si) or germanium (Ge). In some embodiments, the channel material may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a combination of semiconductor materials.

For some example n-type transistor embodiments (i.e., for the embodiments where the transistor in which the channel material is included is an NMOS transistor), the channel material may include a III-V material having a relatively high electron mobility, such as, but not limited to InGaAs, InP, InSb, and InAs. For some such embodiments, the channel material may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor in which the channel material is included is a PMOS transistor), the channel material may advantageously be a group IV material having a high hole mobility, such as, but not limited to Ge or a Ge-rich SiGe alloy. For some example embodiments, the channel material may have a Ge content between 0.6 and 0.9, and advantageously may be at least 0.7.

In some embodiments, the channel material may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

As noted above, the channel material may include IGZO. IGZO-based devices have several desirable electrical and manufacturing properties.

IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors. IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium: gallium: zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In some embodiments, any of the transistors described herein, e.g., the transistor 410, may be a thin-film transistor (TFT). A TFT is a special kind of a FET made by depositing active semiconductor material over a support (e.g., a support structure as described above) that may be a non-conducting support. Some such materials may be deposited at relatively low temperatures, which allows depositing them within the thermal budgets imposed on back-end fabrication to avoid damaging the front-end components such as the logic devices of an IC device in which the transistor may be included. Thus, in some embodiments, the channel material of any of the transistors described herein, e.g., the transistor 410, may be a semiconductor material deposited at relatively low temperatures, and may include any of the oxide semiconductor materials described above.

In other embodiments, instead of being deposited at relatively low temperatures as described above with reference to the TFTs, the channel material of any of the transistors described herein, e.g., the transistor 410, may be epitaxially grown in what typically involves relatively high-temperature processing. In such embodiments, the channel material may include any of the semiconductor materials described above, including oxide semiconductor materials. In some such embodiments, the channel material may be epitaxially grown directly on a semiconductor layer of a support structure over which the transistor will be fabricated, in a process known as “monolithic integration. ” In other such embodiments, the channel material of any of the transistors described herein, e.g., the transistor 410, may be epitaxially grown on a semiconductor layer of another support structure and then the epitaxially grown layer of the channel material may be transferred, in a process known as a “layer transfer,” to a support structure over which the transistor will reside (e.g., the support 402), in which case the latter support structure may but does not have to include a semiconductor layer prior to the layer transfer. Layer transfer advantageously allows forming non-planar transistors, such as FinFETs or nanoribbon transistors, over support structures or in layers that do not include semiconductor materials (e.g., in the back end of an IC device). Layer transfer also advantageously allows forming transistors of any architecture (e.g., non-planar or planar transistors) without imposing the negative effects of the relatively high-temperature epitaxial growth process on devices that may already be present over a support structure.

A channel material that is deposited at relatively low temperatures is typically a polycrystalline, polymorphous, or amorphous semiconductor, or any combination thereof. A channel material that is epitaxially grown is typically a highly crystalline (e.g., monocrystalline or single-crystalline) material. Therefore, whether the channel material of any of the transistors described herein, e.g., the transistor 410, is deposited at relatively low temperatures or epitaxially grown can be identified by inspecting grain size of the active portions of the channel material (e.g., of the portions of the channel material that form channels of transistors). An average grain size of a channel material of any of the transistors described herein, e.g., the transistor 410, being between about 0.5 and 1 millimeters (in which case the material may be polycrystalline) or smaller than about 0.5 millimeter (in which case the material may be polymorphous or amorphous) may be indicative of the channel material having been deposited (e.g., in which case the transistors in which such a channel material is included are TFTs). On the other hand, an average grain size of a channel material of any of the transistors described herein, e.g., the transistor 410, being equal to or greater than about 1 millimeter (in which case the material may be a single-crystal material) may be indicative of the channel material having been epitaxially grown and included in the final device either by monolithic integration or by layer transfer.

In some embodiments, the channel material of any of the transistors described herein, e.g., the transistor 410, may include a two-dimensional (2D) semiconductor material, i.e., a semiconductor material with a thickness of a few nanometers or less, where electrons in the material are free to move in the 2D plane but their restricted motion in the third direction is governed by quantum mechanics. In some such embodiments, such a channel material may include a single atomic monolayer of a 2D semiconductor material, while, in other such embodiments, such a channel material may include five or more atomic monolayers of a 2D semiconductor material. Examples of 2D materials that may be used to implement the channel material of any of the transistors described herein include, but are not limited to, graphene, hexagonal boron nitride, or transition-metal chalcogenides.

A gate stack 412 including a gate electrode material 408 and, optionally, a gate insulator 406, may wrap entirely or almost entirely around a portion of the nanoribbon 404 as shown in FIG. 4, with the channel portion of the transistor 410 being the active region (channel region) of the channel material in the portion of the nanoribbon 404 wrapped by the gate stack 412. As shown in FIG. 4, the gate insulator 406 may wrap around a transversal portion/cross-section of the nanoribbon 404, and the gate electrode material 408 may wrap around the gate insulator 406.

The gate electrode material 408 may include at least one P-type work function metal or n-type work function metal, depending on whether the transistor 410 is a PMOS transistor or an NMOS transistor. P-type work function metal may be used as the gate electrode material 408 when the transistor 410 is a PMOS transistor and n-type work function metal may be used as the gate electrode material 408 when the transistor 410 is an NMOS transistor. For a PMOS transistor, metals that may be used for the gate electrode material 408 may include, but are not limited to, ruthenium, palladium, platinum, cobalt, nickel, and conductive metal oxides (e.g., ruthenium oxide). For an NMOS transistor, metals that may be used for the gate electrode material 408 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 408 may include a stack of two or more metal layers, where one or more metal layers are work function metal layers and at least one metal layer is a fill metal layer. Further layers may be included next to the gate electrode material 408 for other purposes, such as to act as a diffusion barrier layer or/and an adhesion layer.

In some embodiments, the gate insulator 406 may include one or more high-k dielectrics including any of the materials discussed herein with reference to the insulator material that may surround portions of the transistor 410. In some embodiments, the high-k dielectric may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate insulator 406 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator 406 during fabrication of the transistor 410 to improve the quality of the gate insulator 406. The gate insulator 406 may have a thickness that may, in some embodiments, be between about 0.5 nanometers and 3 nanometers, including all values and ranges therein (e.g., between about 1 and 3 nanometers, or between about 1 and 2 nanometers), although, in other embodiments, the thickness of the gate insulator 406 may be greater than 3 nanometers. In some embodiments, the gate stack 412 may be surrounded by a gate spacer, not shown in FIG. 4. Such a gate spacer would be configured to provide separation between the gate stack 412 and S/D contacts (not shown) of the transistor 410 and could be made of a low-k dielectric material, some examples of which have been provided above. A gate spacer may include pores or air gaps to further reduce its dielectric constant.

Turning to the S/D regions 414, 416 of the transistor 410, in some embodiments, the S/D regions may be highly doped, e.g., with dopant concentrations of at least about 10²⁰ or at least about 10²¹ cm⁻³, in order to advantageously form Ohmic contacts with the respective S/D electrodes, although these regions may also have lower dopant concentrations and may form Schottky contacts in some implementations. Irrespective of the exact doping levels, the S/D regions of a transistor may be the regions having dopant concentration higher than in other regions, e.g., higher than a dopant concentration in the channel portion (i.e., in a channel material extending between the first S/D region 414 and the second S/D region 416), and, therefore, may be referred to as “highly doped” (HD) regions. The channel portion of the transistor 410 may include semiconductor materials with doping concentrations significantly smaller than those of the S/D regions 414, 416.

The S/D regions 414, 416 of the transistor 410 may generally be formed using either an implantation/diffusion process or an etching/deposition process. In the former process, dopants such as boron, aluminum, antimony, phosphorous, or arsenic may be ion-implanted into the nanoribbon 404 to form the source and drain regions. An annealing process that activates the dopants and causes them to diffuse further into the nanoribbon 404 may follow the ion implantation process. In the latter process, portions of the nanoribbon 404 may first be etched to form recesses at the locations of the future S/D regions 414, 416. An epitaxial deposition process may then be carried out to fill the recesses with material that is used to fabricate the S/D regions 414, 416. In some implementations, the S/D regions 414, 416 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 414, 416 may be formed using one or more alternate semiconductor materials such as germanium or a group III-V material or alloy. And in further embodiments, one or more layers of metal and/or metal alloys may be used to form the S/D regions 414, 416. In some embodiments, a distance between the first S/D region 414 and the second S/D regions 416 (i.e., a dimension measured along the longitudinal axis 420 of the nanoribbon 404) may be between about 5 and 40 nanometers, including all values and ranges therein (e.g., between about 22 and 35 nanometers, or between about 20 and 30 nanometers).

FIG. 5 provides a perspective view of an example IC structure 500 implementing a FinFET 510 that may be included in a clock synchronization circuit with Gunn diodes, in accordance with some embodiments. The FinFET 510 is another example of how any of the transistors M1-M3 of the clock synchronization circuits 300 may be implemented in various IC structures and assemblies described herein.

As shown in FIG. 5, a fin 504 may extend away from a support 502. The fin 504 may be formed of one or more semiconductor materials described with reference to the nanoribbon 404. A FinFET 510 may be formed on the basis of the fin 504 by having a gate stack 512 at least partially wrap around a channel portion of the fin 504 and by having source and drain regions, shown in FIG. 5 as a first S/D region 514 and a second S/D region 516, on either side of the gate stack 512. As shown in FIG. 5, the gate stack 512 includes a gate electrode material 508 and a gate insulator 506, each of which wraps entirely or almost entirely around the channel portion of the fin 504, although in other embodiments of the IC structure 500 the gate insulator 506 may be absent. Descriptions provided above with reference to the support 402, the gate stack 412, the gate electrode material 408, the gate insulator 406, and the S/D regions 414, 416 are applicable to, respectively, the support 502, the gate stack 512, the gate electrode material 508, the gate insulator 506, and the S/D regions 514, 516, and, therefore, in the interests of brevity, are not repeated. FIG. 5 further illustrates an STI 530, enclosing sidewalls of a subfin portion of the fin 504. The STI 530 may include any of the insulator materials described above, e.g., any suitable ILD materials.

A longitudinal axis 520 of the fin 504 may be along the x-axis of the coordinate system 405 and is shown in FIG. 5 with a dashed line. The FinFET 510 may have a gate length (i.e., a distance between the first S/D region 514 and the second S/D region 516), a dimension measured along the longitudinal axis 520, which may, in some embodiments, be between 2 and 60 nanometers, including all values and ranges therein (e.g., between 5 and 20 nanometers, or between 5 and 30 nanometers). Although the fin 504 is illustrated in FIG. 5 as having a rectangular cross-section in an y-z plane, the fin 504 may instead have a cross-section that is rounded or sloped at the “top” of the fin 504, and the gate stack 512 may conform to this rounded or sloped fin 504. In use, the FinFET 510 may form conducting channels on three “sides” of the fin 504, potentially improving performance relative to single-gate transistors (which may form conducting channels on one “side” of a channel material or substrate) and double-gate transistors (which may form conducting channels on two “sides” of a channel material or substrate).

In some embodiments, either the nanoribbon 404 or the fin 504 may be an elongated semiconductor structure based on which any of the transistors of clock synchronization circuits with Gunn diodes described herein may be built, e.g., the transistor 410 or the FinFET 510 may be used to implement any of the transistors M1-M3 of a clock synchronization circuit 300. In the following, IC structures shown in FIGS. 6A-6B and in FIGS. 7A-7D illustrate IC structures with nanoribbons 404 (i.e., the transistors shown in these drawings are nanoribbon transistors similar to the transistor 410). However, descriptions of clock synchronization circuits with Gunn diodes are equally applicable to IC structures with FinFETs, or IC structures where transistors are implemented as planar transistors.

FIGS. 6A-6B provide different views of an example IC structure 600 implementing a clock synchronization circuit with Gunn diodes when transistors M1-M3 are formed along a single stack of nanoribbons 404, according to some embodiments of the present disclosure. FIGS. 6A-6B illustrate an example where three nanoribbons 404 are stacked above one another. Thus, FIGS. 6A-6B illustrate an example where each of the transistors M1-M3 of the clock synchronization circuits 300 is a transistor 410 with channel portions in three nanoribbons 404 of the stack. However, in other embodiments, the IC structure 600 may include a stack of nanoribbons 404 with any number of one or more nanoribbons 404. FIG. 6A illustrates a cross-sectional side view of the IC structure 600, with a cross-section taken along the longitudinal axis 420 of the nanoribbons 404, while FIG. 6B illustrates a top-down view of the IC structure 600 (with some of the layers, e.g., layers of insulator material in between various portions, not shown in order to not obscure the view of the elements being explained). In particular, FIG. 6A illustrates the IC structure 600 in a view of an x-z plane of the coordinate system 405 along the plane AA shown in FIG. 6B, while FIG. 6B illustrates the IC structure 600 in a view of an x-y plane of the coordinate system 405 along the plane BB shown in FIG. 6A.

Since each of the transistors M1-M3 of the IC structure 600 is a transistor 410 as described with reference to FIG. 4 but with a stack of multiple nanoribbons 404 instead of a single nanoribbon 404, reference numerals that are the same as those used in FIG. 4 are used to illustrate the same/analogous elements in FIGS. 6A-6B. In FIGS. 6A-6B, a number of elements referred to in the description are illustrated in these figures with different patterns, with a legend showing the correspondence between the reference numerals and patterns being provided at the bottom of the drawing pages. For example, the legend in FIG. 6A illustrates that FIG. 6A uses different patterns to show nanoribbons 404, the gate insulator 406, the gate electrode material 408, a S/D region 442 (which may be either the first S/D region 414 or the second S/D region 316 of the transistors M1-M3), an insulator material 444, and a conductor 446. Each of the transistors M1-M3 shown in FIGS. 6A-6B include a gate comprising the gate insulator 406 and the gate electrode material 408, where the gates of different ones of the transistors M1-M3 are labeled as VG1, VGC, and VG2, in accordance with the labels of FIGS. 3A-3H. Thus, the gate of the IC structure 600 labeled as VG1 (referred to herein as a “gate VG1”) is the gate 312-1 of the transistor M1, the gate of the IC structure 600 labeled as VG2 (referred to herein as a “gate VG2”) is the gate 312-2 of the transistor M2, and the gate of the IC structure 600 labeled as VGC (referred to herein as a “gate VGC”) is the gate 312-3 of the transistor M3. Each of the transistors M1-M3 of the IC structure 600 has one of the S/D regions 442 on one side of its gate and another one of the S/D regions 442 on the other side of its gate. Approximate outlines of different ones of the transistors M1-M3 are shown in FIGS. 6A-6B with a dashed contours for the transistors M1 and M2 and with a dotted contour for the transistor M3.

The Gunn diodes GD1-GD2 of the IC structure 600 are the Gunn diodes GD1-GD2 as described with reference to FIGS. 3A-3H, having a top electrode 462, a bottom electrode 464, and a Gunn diode stack 466. Similar to the notation used in FIGS. 3A-3H, the top electrode 462, the bottom electrode 464, and the Gunn diode stack 466 of different Gunn diodes are denoted in FIGS. 6A-6B with different reference numerals after the dash, the reference numerals being the same as in one of the Gunn diodes GD1-GD2. The top electrode 462 is the electrode of a Gunn diode that is further away from the support 402 than the bottom electrode 464, and the bottom electrode 464 is the one closer to the support 402 than the top electrode 462 and the one coupled (e.g., directly electrically connected) to either the node N1 or the node N2, depending on whether the Gunn diode is the Gunn diode GD1 or GD2 of the clock synchronization circuits 300. For a given Gunn diode of the IC structure 600, one of the top electrode 462 and the bottom electrode 464 is the first electrode 362 and the other one is the second electrode 364, depending on the arrangement of the ground voltage 332 and the supply voltage 334 for the IC structure 600 (said arrangement not shown in FIGS. 6A-6B, but being as described with reference to the clock synchronization circuits 300 of FIGS. 3A-3H). The insulator material 444 may be provided around various portions of the IC structure 600 to provide electrical isolation and mechanical stability. The insulator material 444 may include any of the suitable insulator materials, e.g., as of the suitable ILD materials.

Because in the IC structure 600 all of the transistors M1-M3 are provided along a single stack of nanoribbons 404, the S/D regions of different ones of the transistors M1-M3 that are coupled to one another in the clock synchronization circuits 300 may be provided as shared S/D regions in the IC structure 600, advantageously enabling more compact structures (e.g., structures with a smaller footprint). Because the transistor M3 of the clock synchronization circuits 300 has its different S/D regions 314-3 and 316-3 coupled to the S/D regions 314 of the transistors M1 and M2, it may be particularly advantageous to arrange the transistor M3 between the transistors M1 and M2 along the stack of nanoribbons 404. Thus, FIGS. 6A-6B illustrate an example embodiment where a single S/D region 442 serves as a shared S/D region between the transistors M1 and M3, shown in the view of FIG. 6A as the S/D region 442 between the gate VG1 and the gate VGC. This shared S/D region 442 corresponds to the node N1 of the clock synchronization circuits 300, which is coupled to the Gunn diode GD1, which is also shown in FIGS. 6A-6B. In particular, the view of FIG. 6A illustrates that the Gunn diode GD1 may be stacked above the S/D region 442 shared between transistors M1 and M3, where the bottom electrode 464-1 of the Gunn diode GD1 may be coupled to the S/D region 442 shared between the transistors M1 and M3, e.g., by means of a conductive via V1 that includes the conductor 446. In other embodiments, any other suitable interconnect may couple the bottom electrode 464-1 of the Gunn diode GD1 and the S/D region 442 shared between the transistors M1 and M3 (e.g., a conductive line instead of a conductive via), or, in some embodiments, the bottom electrode 464-1 of the Gunn diode GD1 may be provided directly over (e.g., in physical/conductive contact with) the S/D region 442 shared between the transistors M1 and M3. Similarly, FIGS. 6A-6B illustrate an example embodiment where a single S/D region 442 serves as a shared S/D region between the transistors M3 and M2, shown in the view of FIG. 6A as the S/D region 442 between the gate VGC and the gate VG1. This shared S/D region 442 corresponds to the node N2 of the clock synchronization circuits 300, which is coupled to the Gunn diode GD2, which is also shown in FIGS. 6A-6B. In particular, the view of FIG. 6A illustrates that the Gunn diode GD2 may be stacked above the S/D region 442 shared between transistors M3 and M2, where the bottom electrode 464-2 of the Gunn diode GD2 may be coupled to the S/D region 442 shared between the transistors M3 and M2, e.g., by means of a conductive via V2 that includes the conductor 446. In other embodiments, any other suitable interconnect may couple the bottom electrode 464-2 of the Gunn diode GD2 and the S/D region 442 shared between the transistors M3 and M2 (e.g., a conductive line instead of a conductive via), or, in some embodiments, the bottom electrode 464-2 of the Gunn diode GD2 may be provided directly over (e.g., in physical/conductive contact with) the S/D region 442 shared between the transistors M3 and M2. The conductor 446 may include any suitable conductive materials for providing an interconnect between the bottom electrodes 464 of the Gunn diodes GD1 and GD2 and corresponding S/D regions 442 to which they are coupled.

FIGS. 7A-7D provide different views of an example IC structure 700 implementing a clock synchronization circuit with Gunn diodes when transistors M1-M3 are formed along different stacks of nanoribbons, according to some embodiments of the present disclosure. FIGS. 7A-7D illustrate an example similar to that of FIGS. 6A-6B, where, three nanoribbons 404 are stacked above one another for a given stack of nanoribbons, but FIGS. 7A-7D illustrate three such stacks, with one for each of the transistors M1-M3. Thus, FIGS. 7A-7D illustrate an example where each of the transistors M1-M3 of the clock synchronization circuits 300 is a transistor 410 with channel portions in three nanoribbons 404 of a respective nanoribbon stack. However, in other embodiments, the IC structure 700 may include stacks of nanoribbons 404 with any number of one or more nanoribbons 404 in each of the stacks. FIG. 7A illustrates a top-down view of the IC structure 700 (with some of the layers, e.g., layers of insulator material in between various portions, not shown in order to not obscure the view of the elements being explained), while each of FIGS. 7B-7D illustrates a cross-sectional side view of the IC structure 700, with cross-sections taken along planes perpendicular to the longitudinal axes 420 of the nanoribbons 404. In particular, FIG. 7A illustrates the IC structure 700 in a view of an x-y plane of the coordinate system 405, FIG. 7B illustrates the IC structure 700 in a view of a y-z plane of the coordinate system 405 along the plane BB shown in FIG. 7A, FIG. 7C illustrates the IC structure 700 in a view of a y-z plane of the coordinate system 405 along the plane CC shown in FIG. 7A, and FIG. 7D illustrates the IC structure 700 in a view of a y-z plane of the coordinate system 405 along the plane DD shown in FIG. 7A.

Since each of the transistors M1-M3 of the IC structure 700 is a transistor 410 as described with reference to FIG. 4 but with a stack of multiple nanoribbons 404 instead of a single nanoribbon 404, reference numerals that are the same as those used in FIG. 4 are used to illustrate the same/analogous elements in FIGS. 7A-7D. Some of the reference numerals that are the same as those used in FIGS. 6A-6B are also used to illustrate the same/analogous elements in FIGS. 7A-7D. Similar to FIGS. 6A-6B, in FIGS. 7A-7D, a number of elements referred to in the description are illustrated in these figures with different patterns, with a legend showing the correspondence between the reference numerals and patterns being provided at the bottom of the drawing pages. For example, the legend in FIG. 7A illustrates that FIG. 7A uses different patterns to show the nanoribbons 404, the gate electrode material 408, the insulator material 444, and the conductor 446. Each of the transistors M1-M3 shown in FIGS. 7A-7D include a gate comprising the gate insulator 406 and the gate electrode material 408, where the gates of different ones of the transistors M1-M3 are labeled as VG1, VGC, and VG2, in accordance with the labels of FIGS. 3A-3H. Thus, the gate of the IC structure 700 labeled as VG1 (referred to herein as a “gate VG1”) is the gate 312-1 of the transistor M1, the gate of the IC structure 700 labeled as VG2 (referred to herein as a “gate VG2”) is the gate 312-2 of the transistor M2, and the gate of the IC structure 700 labeled as VGC (referred to herein as a “gate VGC”) is the gate 312-3 of the transistor M3. Each of the transistors M1-M3 of the IC structure 700 has one of the S/D regions 442 on one side of its gate and another one of the S/D regions 442 on the other side of its gate. Approximate outlines of different ones of the transistors M1-M3 are shown in FIGS. 7A-7D with a dashed contours for the transistors M1 and M2 and with a dotted contour for the transistor M3.

The Gunn diodes GD1-GD2 of the IC structure 700 are the Gunn diodes GD1-GD2 as described with reference to FIGS. 3A-3H, having a top electrode 462, a bottom electrode 464, and a Gunn diode stack 466 as were described with reference to FIGS. 6A-6B. Similar to the notation used in FIGS. 3A-3H, the top electrode 462, the bottom electrode 464, and the Gunn diode stack 466 of different Gunn diodes are denoted in FIGS. 7A-7D with different reference numerals after the dash, the reference numerals being the same as in one of the Gunn diodes GD1-GD2. The top electrode 462 is the electrode of a Gunn diode that is further away from the support 402 than the bottom electrode 464, and the bottom electrode 464 is the one closer to the support 402 than the top electrode 462 and the one coupled (e.g., directly electrically connected) to either the node N1 or the node N2, depending on whether the Gunn diode is the Gunn diode GD1 or GD2 of the clock synchronization circuits 300. For a given Gunn diode of the IC structure 700, one of the top electrode 462 and the bottom electrode 464 is the first electrode 362 and the other one is the second electrode 364, depending on the arrangement of the ground voltage 332 and the supply voltage 334 for the IC structure 700 (said arrangement not shown in FIGS. 7A-7D, but being as described with reference to the clock synchronization circuits 300 of FIGS. 3A-3H). The insulator material 444 may be provided around various portions of the IC structure 700 to provide electrical isolation and mechanical stability.

Because in the IC structure 700 the transistors M1-M3 are provided along different stacks of nanoribbons 404, the S/D regions of different ones of the transistors M1-M3 that are coupled to one another in the clock synchronization circuits 300 may be provided as different stacks of nanoribbons 404 but connected to one another by means of conductive lines L1 and L2. Because the transistor M3 of the clock synchronization circuits 300 has its different S/D regions 314-3 and 316-3 coupled to the S/D regions 314 of the transistors M1 and M2, it may be particularly advantageous to arrange the stack of nanoribbons 404 of the transistor M3 between the stack of nanoribbons 404 of the transistor M1 and the stack of nanoribbons 404 of the transistor M2. The conductive line L1 of the IC structure 700 may be used to couple the bottom electrode 364-1 of the Gunn diode GD1 to the first S/D region 314-1 of the transistor M1 in the first stack of nanoribbons 404 and the first S/D region 314-3 of the transistor M3 in the third stack of nanoribbons 404, thus realizing the node N1 of the clock synchronization circuits 300. Similarly, the conductive line L2 of the IC structure 700 may be used to couple the bottom electrode 364-2 of the Gunn diode GD2 to the first S/D region 314-2 of the transistor M2 in the second stack of nanoribbons 404 and the second S/D region 316-3 of the transistor M3 in the third stack of nanoribbons 404, thus realizing the node N2 of the clock synchronization circuits 300. In other embodiments, any other suitable interconnect may be used in place of the conductive lines L1 and L2, e.g., any suitable combination of conductive lines and conductive vias. While in the IC structure 700 the Gunn diode GD1 is shown to be stacked above the S/D region 442 of the transistor M1, in other embodiments the Gunn diode GD1 may be arranged anywhere else, as long as it can be coupled as described herein by means of the conductive line L1 or any other suitable interconnect. While in the IC structure 700 the Gunn diode GD2 is shown to be stacked above the S/D region 442 of the transistor M2, in other embodiments the Gunn diode GD2 may be arranged anywhere else, as long as it can be coupled as described herein by means of the conductive line L2 or any other suitable interconnect.

FIGS. 8A-8H are schematic illustrations of various embodiments of microelectronic assemblies 800 with clock synchronization circuits with Gunn diodes, according to some embodiments of the present disclosure. Each of FIGS. 8A-8H illustrates transistors 802 and Gunn diodes 804, implemented in various layers. The transistors 802 may include one or more (e.g., all of) the transistors M1-M3 of the clock synchronization circuits 300 described herein (e.g., of the IC structure 600, of the IC structure 700, or of any further embodiments of such IC structures), while the Gunn diodes 804 may include one or more (e.g., both of) the Gunn diodes G1-GD2 of the clock synchronization circuits 300 described herein (e.g., of the IC structure 600, of the IC structure 700, or of any further embodiments of such IC structures).

In general, the clock synchronization circuits 300, e.g., any embodiments of the IC structure 600, of the IC structure 700, or of any further embodiments of such IC structures according to any embodiments described herein may be implemented as part of front-end-of-line (FEOL) layer, as part of back-end-of-line (BEOL) layers, and may be provided either on the front side or on the back side of the FEOL layer.

FEOL and BEOL are two distinct stages in semiconductor manufacturing (e.g., in advanced complementary metal-oxide-semiconductor (CMOS) processes), each playing an important role in the fabrication of IC structures (or, more generally, of semiconductor devices). These terms refer to the chronological order of processes involved in creating an IC structure. The FEOL processes occur at the front or early stages of semiconductor manufacturing, typically on the surface of a semiconductor (e.g., silicon) wafer. In the FEOL, individual semiconductor devices components (e.g., transistor, capacitors, resistors, etc.) can be patterned in a wafer. In the BEOL, interconnect structures such as conductive lines and conductive vias, separated as needed by an insulator material, can be formed to provide connection between individual components. The BEOL usually starts with forming the first metal layer on the wafer. The first metal layer is often called M0. More metal layers can be formed on top of M0, and these metal layers are often called M1, M2, and so on. The BEOL layers comprising interconnect structures separated by an insulator material are typically referred to as “backend layers. ” The BEOL layers provided on top of the FEOL layer may be described as being provided on the “front side” of a microelectronic assembly, while the BEOL layers provided on the back of the FEOL layer may be described as being provided on the “back side” of a microelectronic assembly.

FIG. 8A illustrates a cross-sectional view of an example microelectronic assembly 800 in which one or more clock synchronization circuits 300 may be implemented, according to some embodiments of the present disclosure. As shown in FIG. 8A, in general, the microelectronic assembly 800 may include a substrate 310, a device layer 320, and one or more (e.g., a plurality) of metal layers 330, individually labeled as a metal layer 330-1 through metal layer 330-N, where N is an integer greater than 1. Together, the metal layers 330 may be referred to as a metallization stack 340. As also shown in FIG. 8A, the microelectronic assembly 800 may further include one or more (e.g., a plurality) of metal layers 360, individually labeled as a metal layer 360-1 through a metal layer 360-M, where M is an integer equal to or greater than 1 and may, but does not have to be, equal to N. Together, the metal layers 360 may be referred to as a metallization stack 370. The side of the substrate 310 on which the device layer 320 is provided is typically referred to as a “front side,” and the other side of the substrate 310 is referred to as a “back side. ” Thus, the device layer 320 and the metal layers 330 are frontside layers, while the metal layers 360 are backside layers. As shown in FIG. 8A, the substrate 310 may be between the device layer 320 on the front side and the metal layers 360 on the back side, and the device layer 320 may be between the substrate 310 and the metallization stack 340.

The substrate 310 may be any suitable support over which the device layer 320 and the metallization stack 340 may be provided. The descriptions provided for the support 402 are applicable to the substrate 310 and, therefore, in the interests of brevity, are not repeated.

The device layer 320 may include any combination of components (e.g., ICs) provided over the substrate 310. For example, in some embodiments, the device layer 320 may include various logic layers, circuits, and devices (e.g., transistors, capacitors, resistors, etc.) to drive and control a logic IC. In some embodiments, the device layer 320 may include memory devices/circuits. The device layer 320 may also be referred to as a “FEOL layer” and the components of the device layer 320 (e.g., transistors) may be referred to as “frontend components.”

Various layers of the metallization stack 340 may be, or include, BEOL layers, which may also be referred to as “backend layers. ” As used herein, the term “metal layer” may refer to a layer that includes electrically conductive interconnect structures (e.g., conductive lines and conductive vias) for providing electrical connectivity between different IC components, e.g., between different components of the device layer 320. Metal layers described herein may also be referred to as “metal” layers to indicate that these layers include electrically conductive interconnect structures which may, but do not have to, be metal. Various metal layers of the metallization stack 340 may be used to interconnect the various inputs and outputs of the active components (e.g., transistors) in the device layer 320. Generally speaking, each of the metal layers of the metallization stack 340 may include a conductive line (also sometimes referred to as a “trench,” a “trace,” or a “metal line”) and/or a conductive via. Conductive lines of a metal layer are interconnects configured for transferring signals and power along electrically conductive (e.g., metal) structures extending in the x-y plane (e.g., in the x or y directions) of the coordinate system 405, while the conductive vias of a metal layer are configured for transferring signals and power through electrically conductive structures extending in the z-direction of the coordinate system 405, e.g., to any of the adjacent metal layers above or below. Accordingly, conductive vias connect interconnect structures (e.g., conductive lines and/or conductive vias) of one metal layer to interconnect structures of an adjacent metal layer. While referred to as “metal” layers, various layers of the metallization stack 340 may include only certain patterns of conductive metals, e.g., copper (Cu), aluminum (Al), tungsten (W), or cobalt (Co), or metal alloys, or more generally, patterns of an electrically conductive material, formed in a medium of an insulator material such as an ILD. The insulator medium may include any suitable ILD materials such as silicon oxide, carbon-doped silicon oxide, silicon carbide, silicon nitride, aluminum oxide, and/or silicon oxynitride.

Various layers of the metallization stack 370 may be, or include, BEOL layers on the back side of the substrate 310, which may also be referred to as “backside backend layers. ” Descriptions provided with respect to the metal layers 330 and the metallization stack 340 are applicable to, respectively, the metal layers 360 and the metallization stack 370 and, in the interest of brevity, are not repeated.

In general, any of the transistors 802 and any of the Gunn diodes 804 of the clock synchronization circuits 300 may be provided in any one or more of the device layer 320 and/or any one or more of the metal layers 330-1 and 330-N of the metallization stack 340 and/or any one or more of the metal layers 360-1 and 360-M of the metallization stack 370.

FIG. 8A illustrates an embodiment where the transistors 802 are implemented in the device layer 320 and the Gunn diodes 804 are implemented in the metal layer 330-1. In other embodiments of the microelectronic assembly 800 of FIG. 8A, the Gunn diodes 804 may be implemented in one or more of the metal layers 330 above the metal layer 330-1. In still other embodiments of the microelectronic assembly 800 of FIG. 8A, the Gunn diodes 804 may be implemented in the metal layer 360-1 or in one or more of the metal layers 360 below the metal layer 360-1.

FIG. 8B illustrates an embodiment similar to that shown in FIG. 8A except that, in the microelectronic assembly 800 of FIG. 8B, the Gunn diodes 804 are implemented in the device layer 320 and the transistors 802 are implemented in the metal layer 330-1. In other embodiments of the microelectronic assembly 800 of FIG. 8B, the transistors 802 may be implemented in one or more of the metal layers 330 above the metal layer 330-1.

FIG. 8C illustrates an embodiment similar to that shown in FIG. 8A except that, in the microelectronic assembly 800 of FIG. 8C the Gunn diodes 804 are implemented in the substrate 310.

FIG. 8D illustrates an embodiment similar to that shown in FIG. 8A except that, in the microelectronic assembly 800 of FIG. 8D, some of the transistors 802 are implemented in the substrate 310 and some of the transistors 802 are implemented in one or more of the metal layers 330. For example, as shown in FIG. 8D, a first subset of the transistors 802 may be implemented in the substrate 310 and a second subset of the transistors 802 may be implemented in the metal layer 330-1. Similar to FIG. 8A, the Gunn diodes 804 may also be implemented in one of the metal layers 330, e.g., in the metal layer 330-N. In other embodiments of the microelectronic assemblies 800B the transistors 802 may be implemented in one or more of the metal layers 330 above the metal layer 330-1.

In some embodiments, once all of the layers on the front side have been fabricated and the microelectronic assembly 800 has been flipped over to continue with fabrication of the metal layers 360 on the back side, the substrate 310 may be thinned (e.g., polished, etched, or otherwise removed) to the point that terminals of the components of the device layer 320 (e.g., S/D regions of the transistors in the device layer 320) may be contacted from the back side. The metal layers 360 may then be provided directly over the back side of the device layer 320. In some such embodiments, the substrate 310 may be substantially removed (but the portions of the substrate 310 in which the frontend devices of the device layer 320 were fabricated may remain), and the device layer 320 may be between the metal layers 330 on the front side and the metal layers 360 on the back side. FIGS. 8E-8H illustrate some example embodiments of the microelectronic assemblies where the substrate 310 is absent.

FIG. 8E illustrates an embodiment similar to that shown in FIG. 8A except that the substrate 310 has been substantially removed.

FIG. 8F illustrates an embodiment similar to that shown in FIG. 8E except (i.e., the substrate 310 has been substantially removed), in the microelectronic assembly 800 of FIG. 8B, the Gunn diodes 804 are implemented in the metal layer 360-1. In other embodiments of the microelectronic assembly 800 of FIG. 8F, the Gunn diodes 804 may be implemented in one or more of the metal layers 360 below the metal layer 360-1.

FIG. 8G illustrates an embodiment where the substrate 310 has been substantially removed and where different ones of the Gunn diodes 804 are implemented on different sides of a layer with the transistors 802. For example, as shown in FIG. 8G, the transistors 802 may be implemented in the device layer 320, one of the Gunn diodes 804 may be implemented in one or more of the metal layers 330 (e.g., in the metal layer 330-1) and the other one of the Gunn diodes 804 may implemented in one or more of the metal layers 360 (e.g., in the metal layer 360-1).

FIG. 8H illustrates an embodiment where the substrate 310 has been substantially removed, the Gunn diodes 804 are implemented in the device layer 320 and the transistors 802 are implemented in one or more of the metal layers 360 (e.g., in the metal layer 360-1).

The illustration of FIGS. 8A-8H is intended to provide a general orientation and arrangement of various layers with respect to one another, and, unless specified otherwise in the present disclosure, includes embodiments of the microelectronic assemblies 800 where portions of elements described with respect to one of the layers shown in FIGS. 8A-8H may extend into one or more, or be present in, other layers. In various embodiments, the metallization stack 340 and/or the metallization stack 370 may be absent from the microelectronic assemblies 800.

Various arrangements (e.g., various devices/circuits/structures/assemblies) as illustrated in FIGS. 1-8 do not represent an exhaustive set of designs that may be used in clock synchronization circuits with Gunn diodes as described herein, but merely provide examples of such arrangements. For example, while FIGS. 6A-6B and FIGS. 7A-7D illustrate embodiments where the transistors M1-M3 are built based on nanoribbons 404, in other embodiments, any of the transistors M1-M3 may be built based on the fins 504 (i.e., any of the transistors M1-M3 may be FinFETs, e.g., as described with reference to FIG. 5). In still further embodiments, any of the transistors M1-M3 may be planar transistors, e.g., any of the transistors M1-M3 may be TFTs (e.g., any of the TFTs with thin-film channel materials as described herein). FIGS. 8A-8H may be extended further to show any subsets of the transistors 802 and any subsets of the Gunn diodes 804 in any of the layers of the microelectronic assemblies 800. The number and positions of various elements shown in FIGS. 1-8 is purely illustrative and, in various other embodiments, other numbers of these elements, provided in other locations relative to one another may be used in accordance with the general architecture considerations described herein.

The clock synchronization circuits with Gunn diodes as described herein, e.g., any embodiments of described with reference to FIGS. 1-8, or any combination of such embodiments, may be included in any suitable electronic device. FIGS. 9-14 illustrate various examples of apparatuses that may include clock synchronization circuits with Gunn diodes, e.g., one or more IC structures and/or microelectronic assemblies with clock synchronization circuits with Gunn diodes disclosed herein (e.g., any embodiments of the clock synchronization circuits 300, any embodiments of the IC structures with clock synchronization circuits with Gunn diodes, and/or any embodiments of the microelectronic assemblies with clock synchronization circuits with Gunn diodes.

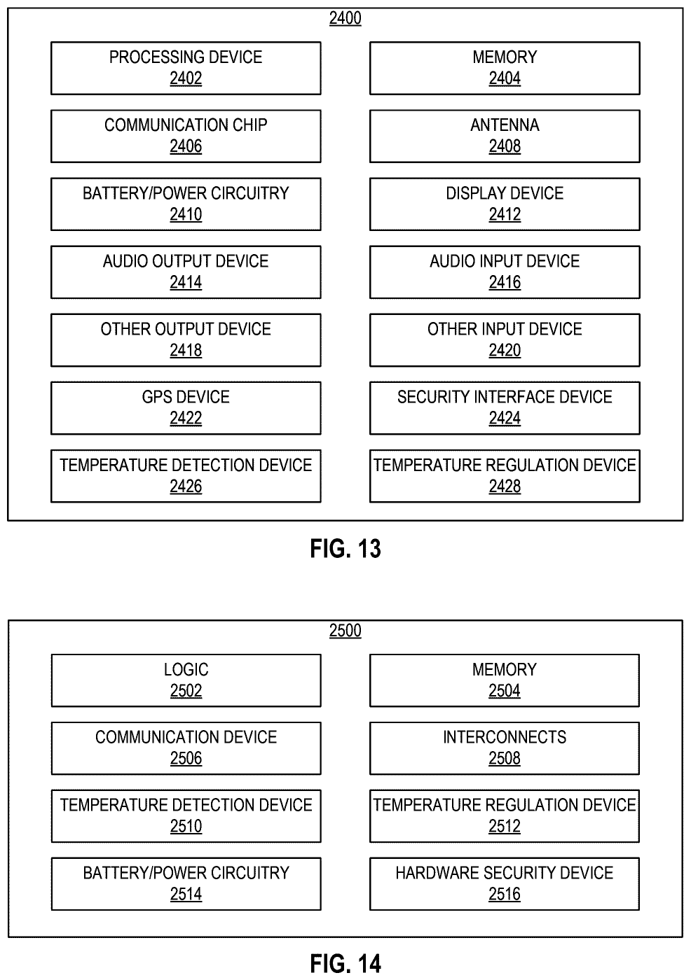

FIG. 9 illustrates top views of a wafer and dies that may include one or more IC structures and/or microelectronic assemblies with clock synchronization circuits with Gunn diodes in accordance with any of the embodiments disclosed herein. The wafer 2000 may be composed of semiconductor material and may include one or more dies 2002 having IC structures formed on a surface of the wafer 2000. Each of the dies 2002 may be a repeating unit of a semiconductor product that includes any suitable IC structure (e.g., any of the IC structures and/or microelectronic assemblies described with reference to FIGS. 1-8). After the fabrication of the semiconductor product is complete (e.g., after manufacture of one or more IC structures and/or after manufacture of one or more microelectronic assemblies with clock synchronization circuits with Gunn diodes as described herein), the wafer 2000 may undergo a singulation process in which each of the dies 2002 is separated from one another to provide discrete “chips” of the semiconductor product. In particular, devices that include one or more IC structures and/or microelectronic assemblies with clock synchronization circuits with Gunn diodes as disclosed herein may take the form of the wafer 2000 (e.g., not singulated) or the form of the die 2002 (e.g., singulated). The die 2002 may include one or more clock synchronization circuits with Gunn diodes, and/or supporting circuitry to route electrical signals to the clock synchronization circuits with Gunn diodes, as well as any other IC components. In some embodiments, the wafer 2000 or the die 2002 may include a memory device (e.g., a memory device with one or more clock synchronization circuits with Gunn diodes), a logic device (e.g., an AND, OR, NAND, or NOR gate, or any other logic device with one or more clock synchronization circuits with Gunn diodes), or any other suitable circuit element. Multiple ones of these devices may be combined on a single die 2002. For example, a memory array formed by multiple memory devices may be formed on a same die 2002 as a processing device (e.g., the processing device 2500 of FIG. 14) or other logic that is configured to store information in the memory devices or execute instructions stored in the memory array.

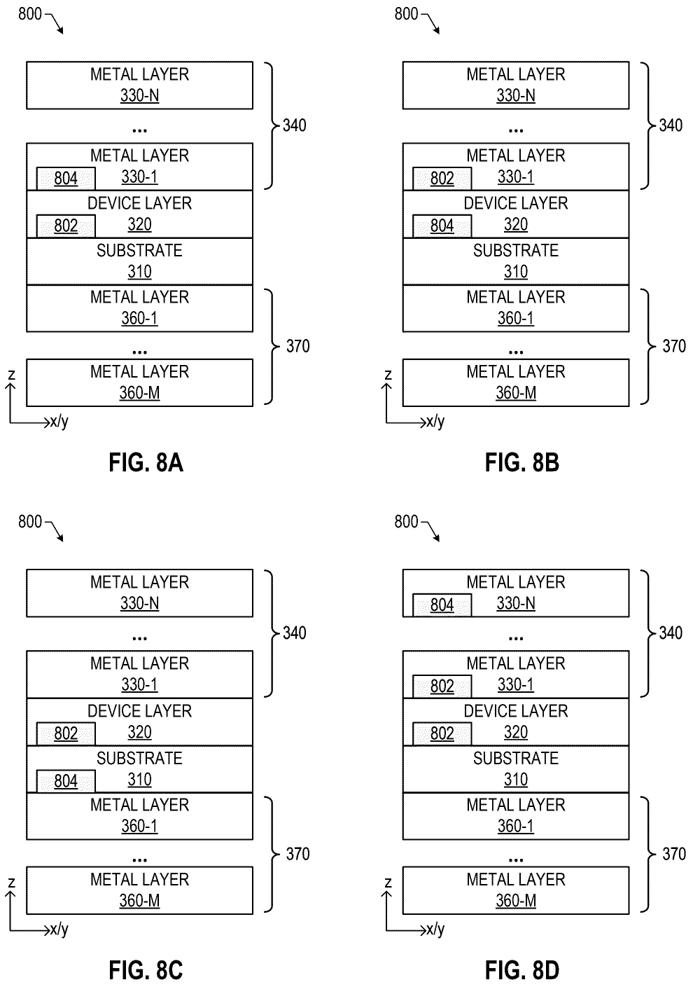

FIG. 10 is a side, cross-sectional view of an IC device 2100 that may include one or more IC structures and/or microelectronic assemblies with clock synchronization circuits with Gunn diodes as described herein, in accordance with various embodiments. For example, any of the transistors of the clock synchronization circuits with Gunn diodes as described herein may be implemented as any of the transistors 2140 of the IC device 2100. In another example, one or more of the IC devices 2100 may be included in one or more dies 2002 of FIG. 9. The IC device 2100 may be formed on a substrate 2102 (e.g., the wafer 2000 of FIG. 9) and may be included in a die (e.g., the die 2002 of FIG. 9). The substrate 2102 may take on any forms of the support 402, the support 502, or the substrate 310, described above.

The IC device 2100 may include one or more device layers 2104 disposed on the substrate 2102. The device layer 2104 may include features of one or more transistors 2140 (e.g., MOSFETs) formed on the substrate 2102. The device layer 2104 may include, for example, one or more S/D regions 2120, a gate 2122 to control current flow in the transistors 2140 between the S/D regions 2120, and one or more S/D contacts 2124 to route electrical signals to/from the S/D regions 2120. The transistors 2140 may include additional features not depicted for the sake of clarity, such as device isolation regions, gate contacts, and the like. The transistors 2140 are not limited to the type and configuration depicted in FIG. 10 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors. In some embodiments, any of the transistors 2140 may be implemented as any of the transistors 410 or 510, described above.

Each transistor 2140 may include a gate 2122 formed of at least two layers, a gate insulator and a gate electrode. The gate insulator of the transistor 2140 may be implemented as the gate insulator 406 or the gate insulator 506, while the gate electrode of the transistor 2140 may be implemented as the gate electrode material 408 or the gate electrode material 508, described above.

The S/D regions 2120 may be formed within the substrate 2102 adjacent to the gate 2122 of each transistor 2140. The S/D regions 2120 of the transistor 2140 may be implemented as the S/D regions of any of the transistors M1-M3, described above.

Electrical signals, such as power and/or input/output (I/O) signals, may be routed to and/or from the devices (e.g., the transistors 2140) of the device layer 2104 through one or more interconnect layers disposed on the device layer 2104 (illustrated in FIG. 10 as interconnect layers 2106, 2108, and 2110). For example, electrically conductive features of the device layer 2104 (e.g., the gate 2122 and the S/D contacts 2124) may be electrically coupled with the interconnect structures 2128 of the interconnect layers 2106, 2108, and 2110. The one or more interconnect layers 2106, 2108, and 2110 may form a metallization stack (also referred to as an “ILD stack”) 2119 of the IC device 2100. Descriptions provided with respect to the device layer 320 are applicable to the device layer 2104 and vice versa. Furthermore, descriptions provided with respect to the metal layers 330 or the metal layers 360 are applicable to the interconnect layers 2106, 2108, and 2110 and vice versa.

The interconnect structures 2128 may be arranged within the interconnect layers 2106, 2108, and 2110 to route electrical signals according to a wide variety of designs (in particular, the arrangement is not limited to the particular configuration of interconnect structures 2128 depicted in FIG. 10). Although a particular number of interconnect layers 2106, 2108, and 2110 is depicted in FIG. 10, embodiments of the present disclosure include IC devices having more or fewer interconnect layers than depicted.

In some embodiments, the interconnect structures 2128 may include lines 2128a and/or vias 2128b filled with an electrically conductive material such as a metal. The lines 2128a may be arranged to route electrical signals in a direction of a plane that is substantially parallel with a surface of the substrate 2102 upon which the device layer 2104 is formed. For example, the lines 2128a may route electrical signals in a direction in and out of the page from the perspective of FIG. 10. The vias 2128b may be arranged to route electrical signals in a direction of a plane that is substantially perpendicular to the surface of the substrate 2102 upon which the device layer 2104 is formed. In some embodiments, the vias 2128b may electrically couple lines 2128a of different interconnect layers 2106, 2108, and 2110 together.

The interconnect layers 2106, 2108, and 2110 may include an insulator material 2126 disposed between the interconnect structures 2128, as shown in FIG. 10. In some embodiments, the insulator material 2126 disposed between the interconnect structures 2128 in different ones of the interconnect layers 2106, 2108, and 2110 may have different compositions; in other embodiments, the composition of the insulator material 2126 between different interconnect layers 2106, 2108, and 2110 may be the same.

A first interconnect layer 2106 may be formed above the device layer 2104. In some embodiments, the first interconnect layer 2106 may include lines 2128a and/or vias 2128b, as shown. The lines 2128a of the first interconnect layer 2106 may be coupled with contacts (e.g., the S/D contacts 2124) of the device layer 2104.

A second interconnect layer 2108 may be formed above the first interconnect layer 2106. In some embodiments, the second interconnect layer 2108 may include vias 2128b to couple the lines 2128a of the second interconnect layer 2108 with the lines 2128a of the first interconnect layer 2106. Although the lines 2128a and the vias 2128b are structurally delineated with a line within each interconnect layer (e.g., within the second interconnect layer 2108) for the sake of clarity, the lines 2128a and the vias 2128b may be structurally and/or materially contiguous (e.g., simultaneously filled during a dual-damascene process) in some embodiments.

A third interconnect layer 2110 (and additional interconnect layers, as desired) may be formed in succession on the second interconnect layer 2108 according to similar techniques and configurations described in connection with the second interconnect layer 2108 or the first interconnect layer 2106. In some embodiments, the interconnect layers that are “higher up” in the metallization stack 2119 in the IC device 2100 (i.e., farther away from the device layer 2104) may be thicker.

The IC device 2100 may include a solder resist material 2134 (e.g., polyimide or similar material) and one or more conductive contacts 2136 formed on the interconnect layers 2106, 2108, and 2110. In FIG. 10, the conductive contacts 2136 are illustrated as taking the form of bond pads. The conductive contacts 2136 may be electrically coupled with the interconnect structures 2128 and configured to route the electrical signals of the transistor(s) 2140 to other external devices. For example, solder bonds may be formed on the one or more conductive contacts 2136 to mechanically and/or electrically couple a chip including the IC device 2100 with another component (e.g., a circuit board). The IC device 2100 may include additional or alternate structures to route the electrical signals from the interconnect layers 2106, 2108, and 2110; for example, the conductive contacts 2136 may include other analogous features (e.g., posts) that route the electrical signals to external components.

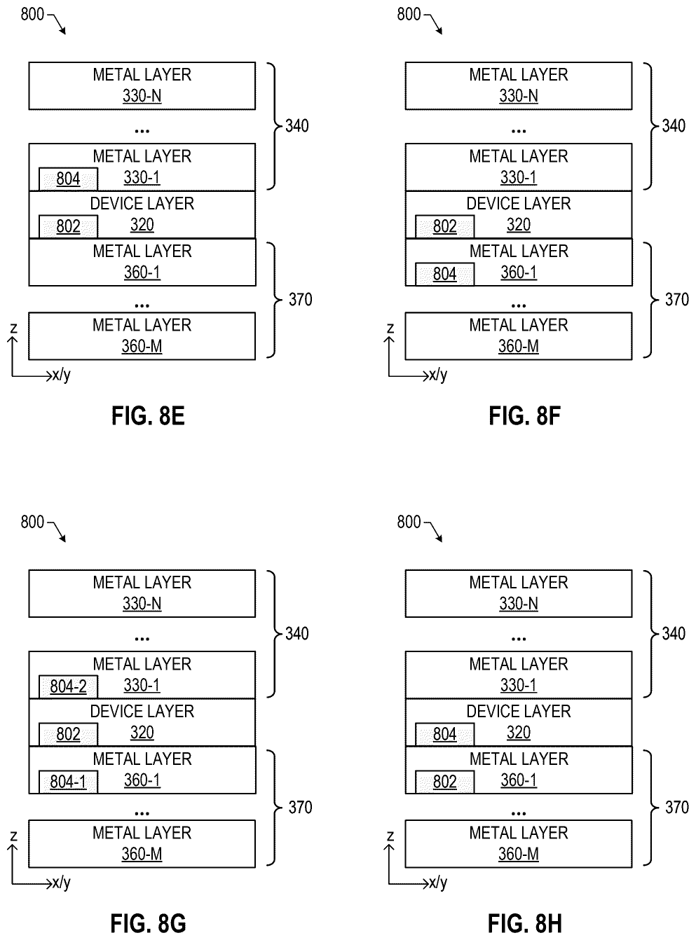

FIG. 11 is a side, cross-sectional view of an example IC package 2200 that may include one or more IC structures and/or microelectronic assemblies with clock synchronization circuits with Gunn diodes, in accordance with various embodiments. For example, in some embodiments, the dies 2202 may include one or more IC structures and/or microelectronic assemblies with any of the clock synchronization circuits with Gunn diodes described herein. In another example, in some embodiments, any of the dies 2202 of the IC package 2200 may be implemented as the die 2002 of FIG. 9. In some embodiments, the dies 2202 may include any of the embodiments of the IC device 2100. In embodiments in which the IC package 2200 includes multiple dies 2202, the IC package 2200 may be referred to as a multi-chip package (MCP). The dies 2202 may include circuitry to perform any desired functionality. For example, or more of the dies 2202 may be logic dies (e.g., silicon-based dies), and one or more of the dies 2202 may be memory dies (e.g., high bandwidth memory). In some embodiments, the IC package 2200 may be a system-in-package (SiP). In some embodiments, the IC package 2200 may include a photonics IC (PIC) co-packaged with an IC package. In some embodiments, the IC package 2200 may include fully integrated electronic photonics ICs (EPICs).

The IC package 2200 may include a package substrate 2204 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 2206 and the face 2208, or between different locations on the face 2206, and/or between different locations on the face 2208. These conductive pathways may take the form of any of the interconnect structures 2128 discussed above with reference to FIG. 10.

The package substrate 2204 may include conductive contacts 2210 that are coupled to conductive pathways (not shown) through the package substrate 2204, allowing circuitry within the dies 2202 and/or the interposer 2212 to electrically couple to various ones of the conductive contacts 2214 (or to other devices included in the package substrate 2204, not shown).

The IC package 2200 may include an interposer 2212 coupled to the package substrate 2204 via conductive contacts 2216 of the interposer 2212, first-level interconnects 2218, and the conductive contacts 2210 of the package substrate 2204. The first-level interconnects 2218 illustrated in FIG. 11 are solder bumps, but any suitable first-level interconnects 2218 may be used. In some embodiments, no interposer 2212 may be included in the IC package 2200; instead, the dies 2202 may be coupled directly to the conductive contacts 2210 at the face 2206 by first-level interconnects 2218. Generally, one or more dies 2202 may be coupled to the package substrate 2204 via any suitable structure (e.g., a silicon bridge, an organic bridge, one or more waveguides, one or more interposers, wirebonds, etc.).

The IC package 2200 may include one or more dies 2202 coupled to the interposer 2212 via conductive contacts 2220 of the dies 2202, first-level interconnects 2222, and conductive contacts 2224 of the interposer 2212. The conductive contacts 2224 may be coupled to conductive pathways (not shown) through the interposer 2212, allowing circuitry within the dies 2202 to electrically couple to various ones of the conductive contacts 2216 (or to other devices included in the interposer 2212, not shown). The first-level interconnects 2222 illustrated in FIG. 11 are solder bumps, but any suitable first-level interconnects 2222 may be used. For example, the first-level interconnects 2222 may include hybrid bonding interconnects. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

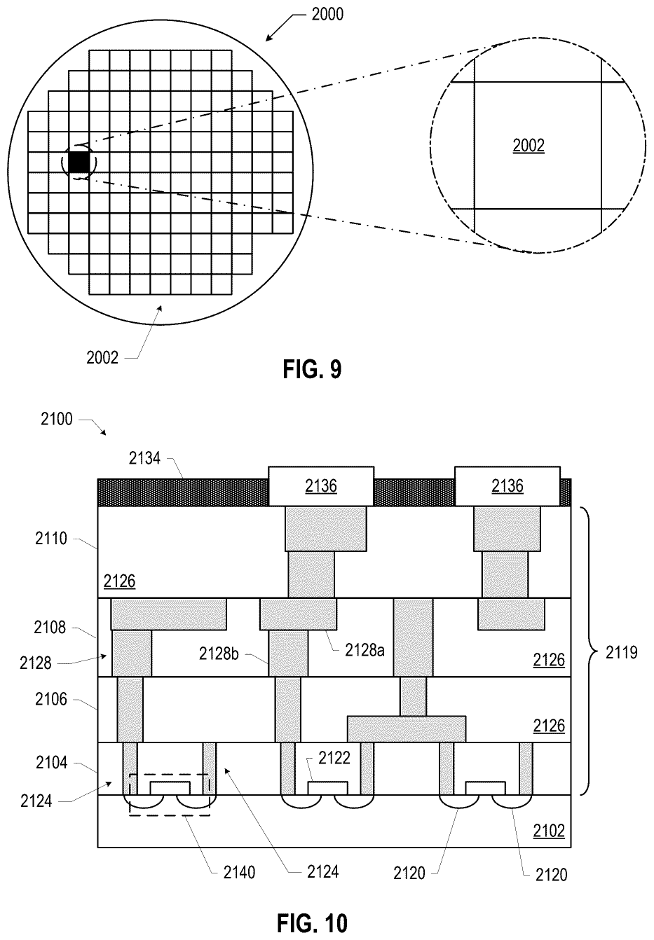

In some embodiments, an underfill material 2226 may be disposed between the package substrate 2204 and the interposer 2212 around the first-level interconnects 2218, and a mold compound 2228 may be disposed around the dies 2202 and the interposer 2212 and in contact with the package substrate 2204. In some embodiments, the underfill material 2226 may be the same as the mold compound 2228. Example materials that may be used for the underfill material 2226 and the mold compound 2228 are epoxy mold materials, as suitable. Second-level interconnects 2230 may be coupled to the conductive contacts 2214. The second-level interconnects 2230 illustrated in FIG. 11 are solder balls (e.g., for a ball grid array arrangement), but any suitable second-level interconnects 2230 may be used (e.g., pins in a pin grid array arrangement or lands in a land grid array arrangement). The second-level interconnects 2230 may be used to couple the IC package 2200 to another component, such as a circuit board (e.g., a motherboard), an interposer, or another IC package, as known in the art and as discussed below with reference to FIG. 12.

Although the IC package 2200 illustrated in FIG. 11 is a flip chip package, other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fanout (FO) package.

Although two dies 2202 are illustrated in the IC package 2200 of FIG. 11, an IC package 2200 may include any desired number of dies 2202. An IC package 2200 may include additional passive components, such as surface-mount resistors, capacitors, and inductors disposed on the first face 2206 or the second face 2208 of the package substrate 2204, or on either face of the interposer 2212. More generally, an IC package 2200 may include any other active or passive components known in the art.

FIG. 12 is a side, cross-sectional view of an IC device assembly 2300 that may include one or more IC packages or other electronic components (e.g., a die) including one or more IC structures and/or microelectronic assemblies with clock synchronization circuits with Gunn diodes in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. Any of the IC packages discussed below with reference to the IC device assembly 2300 may take the form of any of the embodiments of the IC package 2200 discussed above with reference to FIG. 11.

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 12 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302 and may include solder balls (as shown in FIG. 12), male and female portions of a socket, an adhesive, an underfill material, and/or any other suitable electrical and/or mechanical coupling structure.

The package-on-interposer structure 2336 may include an IC package 2320 coupled to a package interposer 2304 by coupling components 2318. The coupling components 2318 may take any suitable form for the application, such as the forms discussed above with reference to the coupling components 2316. Although a single IC package 2320 is shown in FIG. 12, multiple IC packages may be coupled to the package interposer 2304; indeed, additional interposers may be coupled to the package interposer 2304. The package interposer 2304 may provide an intervening substrate used to bridge the circuit board 2302 and the IC package 2320. The IC package 2320 may be or include, for example, a die (the die 2002 of FIG. 9), an IC device (e.g., the IC device 2100 of FIG. 10), or any other suitable component. Generally, the package interposer 2304 may spread a connection to a wider pitch or reroute a connection to a different connection. For example, the package interposer 2304 may couple the IC package 2320 (e.g., a die) to a set of BGA conductive contacts of the coupling components 2316 for coupling to the circuit board 2302. In the embodiment illustrated in FIG. 12, the IC package 2320 and the circuit board 2302 are attached to opposing sides of the package interposer 2304; in other embodiments, the IC package 2320 and the circuit board 2302 may be attached to a same side of the package interposer 2304. In some embodiments, three or more components may be interconnected by way of the package interposer 2304. In some embodiments, the IC package 2320 may include one or more IC structures and/or microelectronic assemblies with clock synchronization circuits with Gunn diodes as disclosed herein.

In some embodiments, the package interposer 2304 may be formed as a PCB, including multiple metal layers separated from one another by layers of dielectric material and interconnected by electrically conductive vias. In some embodiments, the package interposer 2304 may be formed of an epoxy resin, a fiberglass-reinforced epoxy resin, an epoxy resin with inorganic fillers, a ceramic material, or a polymer material such as polyimide. In some embodiments, the package interposer 2304 may be formed of alternate rigid or flexible materials that may include the same materials described above for use in a semiconductor substrate, such as silicon, germanium, and other group III-V and group IV materials. The package interposer 2304 may include metal lines 2310 and vias 2308, including but not limited to through-silicon vias (TSVs) 2306. The package interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 12 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

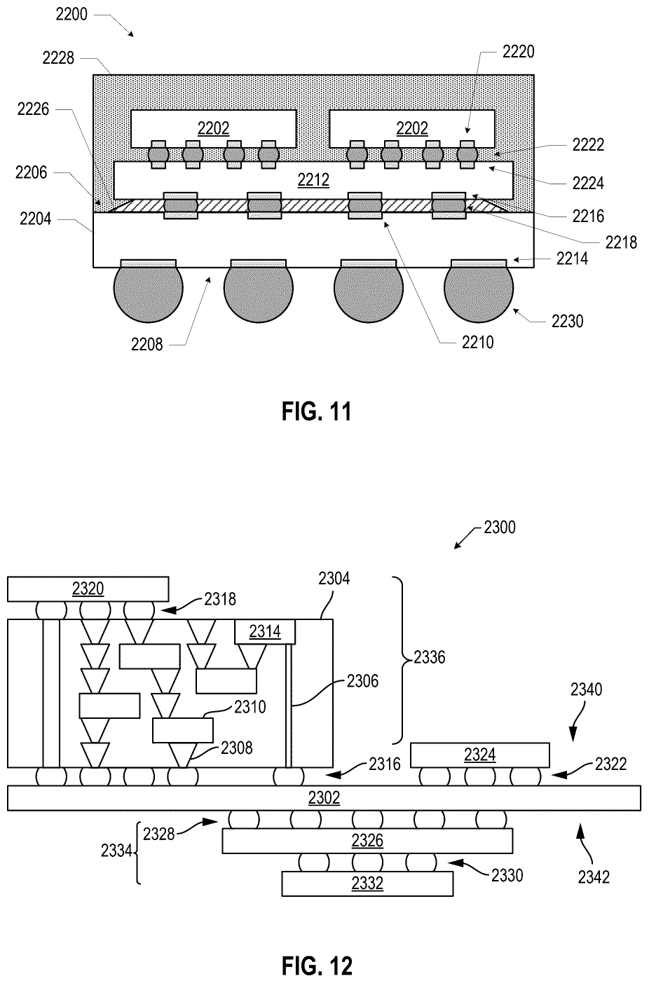

FIG. 13 is a block diagram of an example computing device 2400 that may include one or more components including one or more IC structures and/or microelectronic assemblies with clock synchronization circuits with Gunn diodes in accordance with any of the embodiments disclosed herein. For example, any suitable ones of the components of the computing device 2400 may include a die (e.g., the die 2002 of FIG. 9) having one or more IC structures and/or microelectronic assemblies with clock synchronization circuits with Gunn diodes as described herein. Any one or more of the components of the computing device 2400 may include an IC device 2100 of FIG. 10, an IC package 2200 of FIG. 11, or an IC device assembly 2300 of FIG. 12.

A number of components are illustrated in FIG. 13 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 13, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414 but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. In some embodiments, the processing device 2402 may include one or more IC structures and/or microelectronic assemblies with clock synchronization circuits with Gunn diodes described herein.

The computing device 2400 may include a memory 2404, which may itself include one or more memory devices such as volatile memory (e.g., DRAM), non-volatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM. In some embodiments, the memory 2404 may include one or more IC structures and/or microelectronic assemblies with clock synchronization circuits with Gunn diodes as described herein.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 14 is a block diagram of an example processing device 2500 that may include one or more IC structures and/or microelectronic assemblies with clock synchronization circuits with Gunn diodes as described herein. For example, any suitable ones of the components of the processing device 2500 may include a die (e.g., the die 2002 of FIG. 9) having one or more IC structures and/or microelectronic assemblies with clock synchronization circuits with Gunn diodes as described herein. Any one or more of the components of the processing device 2500 may include an IC device 2100 of FIG. 10, an IC package 2200 of FIG. 11, or an IC device assembly 2300 of FIG. 12. Any one or more of the components of the processing device 2500 may include, or be included in, a computing device 2400 of FIG. 13; for example, the processing device 2500 may be the processing device 2402 of the computing device 2400.

A number of components are illustrated in FIG. 14 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 14, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 13). In some embodiments, the memory 2504 may be a designated device configured to provide storage functionality for the components of the processing device 2500 (e.g., local), while the memory 2404 may be configured to provide system-level storage functionality for the entire computing device 2400 (e.g., global). In some embodiments, the memory 2504 may include memory that shares a die with the logic circuitry 2502.

The processing device 2500 may include a communication device 2506, which may be implemented substantially as described above with reference to the communication chip 2406 (FIG. 13). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”). In some embodiments, the interconnects 2508 may be implemented as the interconnect structures 2128 of FIG. 10, described above.

The processing device 2500 may include a temperature detection device 2510 which may be implemented substantially as described above with reference to the temperature detection device 2426 of FIG. 13 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 13 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 13. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 13. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide examples of various ones of the embodiments disclosed herein.

Example 1 provides an IC structure that includes a plurality of transistors including a first transistor (e.g., transistor M1), a second transistor (e.g., transistor M2), and a third transistor (e.g., transistor M3); a first Gunn diode coupled (e.g., directly electrically connected) to the first transistor; and a second Gunn diode coupled (e.g., directly electrically connected) to the second transistor, wherein the third transistor is coupled between (e.g., directly electrically connected to each of) the first Gunn diode and the second Gunn diode.

Example 2 provides the IC structure according to example 1, wherein an individual transistor of the plurality of transistors includes a first region, a second region, and a gate, wherein one of the first region and the second region is a source region and another one of the first region and the second region is a drain region, and an individual Gunn diode includes a first electrode and a second electrode, and wherein the first electrode of the first Gunn diode is coupled to the first region of the first transistor, and the first electrode of the second Gunn diode is coupled to the first region of the second transistor.

Example 3 provides the IC structure according to example 2, wherein the first electrode of the first Gunn diode is further coupled to the first region of the third transistor, and the first electrode of the second Gunn diode is further coupled to the second region of the third transistor.

Example 4 provides the IC structure according to example 3, wherein the first region of the first transistor is further coupled to the first region of the third transistor, and the first region of the second transistor is further coupled to the second region of the third transistor.

Example 5 provides the IC structure according to any one of examples 2-4, wherein the second region of the first transistor is coupled (e.g., directly electrically connected) to the second region of the second transistor.

Example 6 provides the IC structure according to any one of examples 2-5, wherein the second electrode of the first Gunn diode is coupled (e.g., directly electrically connected) to the second electrode of the second Gunn diode.

Example 7 provides the IC structure according to any one of examples 2-6, wherein the second region of the first transistor and the second region of the second transistor are coupled (e.g., directly electrically connected) to a supply voltage, and the second electrode of the first Gunn diode and the second electrode of the second Gunn diode are coupled (e.g., directly electrically connected) to a ground voltage.

Example 8 provides the IC structure according to any one of examples 2-6, wherein the second region of the first transistor and the second region of the second transistor are coupled (e.g., directly electrically connected) to a ground voltage, and the second electrode of the first Gunn diode and the second electrode of the second Gunn diode are coupled (e.g., directly electrically connected) to a supply voltage.

Example 9 provides the IC structure according to any one of the preceding examples, wherein the first Gunn diode includes a first semiconductor region, a second semiconductor region, and a third semiconductor region, wherein the second semiconductor region is between the first semiconductor region and the third semiconductor region and has a lower dopant concentration than the first semiconductor region and the third semiconductor region.

Example 10 provides the IC structure according to example 9, wherein the first semiconductor region is between the first electrode of the first Gunn diode and the second semiconductor region.

Example 11 provides the IC structure according to examples 9 or 10, wherein the third semiconductor region is between the second semiconductor region and the second electrode of the first Gunn diode.

Example 12 provides an IC structure that includes a first layer including an elongated structure (e.g., a fin or a nanoribbon) of a semiconductor material; a plurality of transistors including a first transistor (e.g., transistor M1), a second transistor (e.g., transistor M2), and a third transistor (e.g., transistor M3), wherein a channel region of the first transistor is in a first portion of the elongated structure, a channel region of the second transistor is in a second portion of the elongated structure, and a channel region of the third transistor is in a third portion of the elongated structure, wherein the third portion is between the first portion and the second portion; a second layer including a first Gunn diode coupled (e.g., directly electrically connected) to the first transistor; and a second Gunn diode coupled (e.g., directly electrically connected) to the second transistor.

Example 13 provides the IC structure according to example 12, wherein a footprint of the first Gunn diode at least partially overlaps with a footprint of a source region or a drain region of the first transistor.

Example 14 provides the IC structure according to examples 12 or 13, wherein an individual transistor of the plurality of transistors includes a first region, a second region, and a gate, one of the first region and the second region is a source region and another one of the first region and the second region is a drain region, and a fourth portion of the elongated structure is the first region of the first transistor and the first region of the third transistor.

Example 15 provides the IC structure according to example 14, wherein the fourth portion is between the first portion and the third portion.

Example 16 provides the IC structure according to examples 14 or 15, wherein a fifth portion of the elongated structure is the first region of the second transistor and the second region of the third transistor.

Example 17 provides the IC structure according to example 16, wherein the fifth portion is between the second portion and the third portion.

Example 18 provides the IC structure according to any one of examples 12-17, wherein the elongated structure is a fin or a nanoribbon.

Example 19 provides an IC structure that includes two or more elongated structures (e.g., a fin or a nanoribbon) of one or more semiconductor materials; a first transistor (e.g., transistor M1), a second transistor (e.g., transistor M2), and a third transistor (e.g., transistor M3), wherein a channel region of at least one of the first transistor, the second transistor, and the third transistor is in a portion of a first of the two or more elongated structures, and a channel region of another one of the first transistor, the second transistor, and the third transistor is in a portion of a second of the two or more elongated structures; a first Gunn diode having an electrode connected (e.g., directly electrically connected) to a source region or a drain region of the first transistor; and a second Gunn diode having an electrode connected (e.g., directly electrically connected) to a source region or a drain region of the second transistor.

Example 20 provides the IC structure according to example 19, wherein a further electrode of the first Gunn diode is connected to a further electrode of the second Gunn diode.

Example 21 provides an IC package, including an IC die, including a transistor; and a further component, coupled to the IC die, wherein the IC die includes an IC structure according to any one of the preceding examples.

Example 22 provides the e IC package according to example 21, wherein the further component is one of a package substrate, an interposer, or a further IC die.

Example 23 provides the IC package according to any one of examples 21-22, further including an insulator material around at least a portion of the IC die.

Example 24 provides the IC package according to any one of examples 21-23, further including interconnects between the further component and the IC die.

Example 25 provides the IC package according to example 24, wherein the interconnects are solder bumps.

Example 26 provides the IC package according to example 24, wherein the interconnects are hybrid bonding interconnects.

Example 27 provides the IC package according to any one of examples 24-26, further including first conductive contacts at a surface of the further component closest to the IC die; and second conductive contacts at a surface of the IC die closest to the further component, wherein the interconnects are between the first conductive contacts and the second conductive contacts.

Example 28 provides the IC package according to example 27, wherein at least one of the first conductive contacts or the second conductive contacts includes a conductive pad.

Example 29 provides the IC package according to example 27, wherein at least one of the first conductive contacts or the second conductive contacts includes a conductive socket.

Example 30 provides the IC package according to any one of examples 21-29, wherein the further component is an interposer, the IC package further includes a package substrate coupled to the interposer, the IC die is coupled to a first face of the interposer, and the package substrate is coupled to a second face of the interposer opposite the first face of the interposer.

Example 31 provides the IC package according to example 30, further including interconnects between the interposer and the package substrate.

Example 32 provides the IC package according to example 31, further including an underfill material around the interconnects.

Example 33 provides an electronic device, including a carrier substrate; and one or more of the transistors or IC structures according to any one of the preceding examples and/or the IC package according to any one of the preceding examples, coupled to the carrier substrate.

Example 34 provides the electronic device according to example 33, wherein the carrier substrate is a motherboard.

Example 35 provides the electronic device according to example 33, wherein the carrier substrate is a PCB.

Example 36 provides the electronic device according to any one of examples 33-35, wherein the electronic device is a wearable electronic device (e.g., a smart watch) or handheld electronic device (e.g., a mobile phone).

Example 37 provides the electronic device according to any one of examples 33-36, wherein the electronic device further includes one or more communication chips and an antenna.

Example 38 provides the electronic device according to any one of examples 33-37, wherein the electronic device is memory device.

Example 39 provides the electronic device according to any one of examples 33-37, wherein the electronic device is a computing device.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a plurality of transistors comprising a first transistor, a second transistor, and a third transistor;
a first Gunn diode coupled to the first transistor; and
a second Gunn diode coupled to the second transistor, wherein the third transistor is coupled between the first Gunn diode and the second Gunn diode.

2. The IC structure according to claim 1, wherein:
an individual transistor of the plurality of transistors includes a first region, a second region, and a gate,
one of the first region and the second region is a source region and another one of the first region and the second region is a drain region, and
an individual Gunn diode includes a first electrode and a second electrode,
wherein the first electrode of the first Gunn diode is coupled to the first region of the first transistor, and the first electrode of the second Gunn diode is coupled to the first region of the second transistor.

3. The IC structure according to claim 2, wherein:
the first electrode of the first Gunn diode is further coupled to the first region of the third transistor, and
the first electrode of the second Gunn diode is further coupled to the second region of the third transistor.

4. The IC structure according to claim 3, wherein:
the first region of the first transistor is further coupled to the first region of the third transistor, and
the first region of the second transistor is further coupled to the second region of the third transistor.

5. The IC structure according to claim 2, wherein:
the second region of the first transistor is coupled to the second region of the second transistor.

6. The IC structure according to claim 2, wherein:
the second electrode of the first Gunn diode is coupled to the second electrode of the second Gunn diode.

7. The IC structure according to claim 2, wherein:
the second region of the first transistor and the second region of the second transistor are coupled to a supply voltage, and
the second electrode of the first Gunn diode and the second electrode of the second Gunn diode are coupled to a ground voltage.

8. The IC structure according to claim 2, wherein:
the second region of the first transistor and the second region of the second transistor are coupled to a ground voltage, and
the second electrode of the first Gunn diode and the second electrode of the second Gunn diode are coupled to a supply voltage.

9. The IC structure according to claim 1, wherein the first Gunn diode includes a first semiconductor region, a second semiconductor region, and a third semiconductor region, wherein the second semiconductor region is between the first semiconductor region and the third semiconductor region and has a lower dopant concentration than the first semiconductor region and the third semiconductor region.

10. The IC structure according to claim 9, wherein the first Gunn diode includes a first electrode and a second electrode, and wherein the first semiconductor region is between the first electrode of the first Gunn diode and the second semiconductor region.

11. The IC structure according to claim 10, wherein the third semiconductor region is between the second semiconductor region and the second electrode of the first Gunn diode.

12. An integrated circuit (IC) structure, comprising:
a first layer comprising an elongated structure of a semiconductor material;
a plurality of transistors comprising a first transistor, a second transistor, and a third transistor, wherein a channel region of the first transistor is in a first portion of the elongated structure, a channel region of the second transistor is in a second portion of the elongated structure, and a channel region of the third transistor is in a third portion of the elongated structure, wherein the third portion is between the first portion and the second portion;
a second layer comprising a first Gunn diode coupled to the first transistor; and
a second Gunn diode coupled to the second transistor.

13. The IC structure according to claim 12, wherein a footprint of the first Gunn diode at least partially overlaps with a footprint of a source region or a drain region of the first transistor.

14. The IC structure according to claim 12, wherein:
an individual transistor of the plurality of transistors includes a first region, a second region, and a gate,
one of the first region and the second region is a source region and another one of the first region and the second region is a drain region, and
a fourth portion of the elongated structure is the first region of the first transistor and the first region of the third transistor.

15. The IC structure according to claim 14, wherein the fourth portion is between the first portion and the third portion.

16. The IC structure according to claim 14, wherein:
a fifth portion of the elongated structure is the first region of the second transistor and the second region of the third transistor.

17. The IC structure according to claim 16, wherein the fifth portion is between the second portion and the third portion.

18. The IC structure according to claim 12, wherein the elongated structure is a fin or a nanoribbon.

19. An integrated circuit (IC) structure, comprising:
two or more elongated structures of one or more semiconductor materials;
a first transistor, a second transistor, and a third transistor, wherein a channel region of at least one of the first transistor, the second transistor, and the third transistor is in a portion of a first of the two or more elongated structures, and a channel region of another one of the first transistor, the second transistor, and the third transistor is in a portion of a second of the two or more elongated structures;
a first Gunn diode having an electrode connected to a source region or a drain region of the first transistor; and
a second Gunn diode having an electrode connected to a source region or a drain region of the second transistor.

20. The IC structure according to claim 19, wherein a further electrode of the first Gunn diode is connected to a further electrode of the second Gunn diode.
